(19) United States
(12) Patent Application Publication
(10) Pub. No.: US 2024/0057430 A1
(43) Pub. Date: Feb. 15, 2024

(54) DISPLAY PANEL AND DISPLAY APPARATUS INCLUDING THE SAME

(71) Applicant: Samsung Display Co., Ltd., Yongin-si (KR)

(72) Inventors: Wonse Lee, Yongin-si (KR); Donghyeon Jang, Yongin-si (KR); Yujin Jeon, Yongin-si (KR)

(21) Appl. No.: 18/340,693

(22) Filed: Jun. 23, 2023

(30) Foreign Application Priority Data
Aug. 11, 2022 (KR) 10-2022-0100732

(51) Int. Cl. H10K 59/35; H10K 59/121; H10K 59/131

(52) U.S. Cl. CPC H10K 59/353; H10K 59/1213; H10K 59/131

(57) ABSTRACT

A display panel includes: a substrate comprising a first area and a second area; a plurality of main sub-pixels in the first area; a plurality of auxiliary sub-pixels in the second area; and a plurality of sub sub-pixels adjacent to a first boundary of the second area in a first direction, wherein the plurality of auxiliary sub pixels comprise a plurality of first auxiliary sub-pixels in a first auxiliary line that is a virtual line extending in the first direction, and a plurality of second auxiliary sub-pixels and a plurality of third auxiliary sub-pixels alternately arranged in a second auxiliary line that is a virtual line parallel to the first auxiliary line, and each of the plurality of sub sub-pixels is between a second auxiliary sub-pixel and a third auxiliary sub-pixel neighboring each other in the first direction.

### CROSS-REFERENCE TO RELATED APPLICATION

The present application claims priority to and the benefit of Korean Patent Application No. 10-2022-0100732, filed on Aug. 11, 2022, in the Korean Intellectual Property Office, the entire disclosure of each of which is incorporated herein by reference.

### BACKGROUND

### 1. Field

Aspects of one or more embodiments relate to a display panel and a display device including the display panel.

### 2. Description of the Related Art

Display devices may be utilized in various applications. In addition, due to their small thicknesses and lighter weight, display devices have a relatively wide range of potential uses or applications.

As display devices may be utilized in various applications, there may be various methods of designing forms of display devices, and functions that may be added to or associated with the display devices are increasing.

The above information disclosed in this Background section is only for enhancement of understanding of the background and therefore the information discussed in this Background section does not necessarily constitute prior art.

### SUMMARY

Aspects of one or more embodiments relate to a display panel and a display device including the display panel, and for example, to a display panel having an extended display area, such that images may be displayed in an area where electronic elements are arranged as components, and a display device including the display panel.

Aspects of one or more embodiments include a display panel having a relatively extended display area, such that images may be displayed even in an area in which electronic elements are arranged as components, and a display device including the display panel. However, this is merely an example, and the scope of the embodiments according to the present disclosure is not limited thereto.

Additional aspects will be set forth in part in the description which follows and, in part, will be apparent from the description, or may be learned by practice of the presented embodiments of the disclosure.

According to some embodiments, a display panel may include a substrate including a first area and a second area, a plurality of main sub-pixels arranged in the first area, a plurality of auxiliary sub-pixels arranged in the second area, and a plurality of sub sub-pixels arranged adjacent to a first boundary of the second area in the first direction, wherein the plurality of auxiliary sub-pixels may be a plurality of first auxiliary sub-pixels arranged in a first auxiliary line that is a virtual line extending in the first direction, and a plurality of second auxiliary sub-pixels and a plurality of third auxiliary sub-pixels alternately arranged in a second auxiliary line that is a virtual line parallel to the first auxiliary line, and each of the plurality of sub sub-pixels may be between the second auxiliary sub-pixel and the third auxiliary sub-pixel neighboring each other in the first direction.

According to some embodiments, the first auxiliary sub-pixel, the second auxiliary sub-pixel, the first auxiliary sub-pixel, and the third auxiliary sub-pixel may be repeatedly arranged in a third auxiliary line that is a virtual line extending in a second direction orthogonal to the first direction.

According to some embodiments, centers of the plurality of sub sub-pixels may overlap with the second auxiliary line.

According to some embodiments, the plurality of sub sub-pixels and the first auxiliary sub-pixels may emit light of a same color.

According to some embodiments, a pixel electrode of any one sub sub-pixel from among the plurality of auxiliary sub-pixels may be electrically connected to a pixel electrode of a first auxiliary sub-pixel adjacent to the any one sub sub-pixel.

According to some embodiments, the display panel may further include a transparent wiring connecting the pixel electrode of the any one sub sub-pixel and the pixel electrode of the first auxiliary sub-pixel adjacent to the any one sub sub-pixel.

According to some embodiments, the pixel electrode of the any one sub sub-pixel and the pixel electrode of the first auxiliary sub-pixel adjacent to the any one sub sub-pixel may be integral with each other.

According to some embodiments, the plurality of main sub-pixels may include a plurality of first main sub-pixels arranged in a first main line that is a virtual line extending in the first direction, and the plurality of second main sub-pixels and the plurality of third main sub-pixels alternately arranged in a second main line that is a virtual line parallel to the first main line, and centers of the first main sub-pixels arranged in the first main line and centers of the second main sub-pixels and the third main sub-pixels arranged in the second main line may be arranged in a zig-zag manner.

According to some embodiments, the second auxiliary line and the first main line may neighbor each other with the first boundary therebetween.

According to some embodiments, the plurality of sub sub-pixels and the first main sub-pixels may emit light of a same color.

According to some embodiments, an area of an emission area of each of the plurality of sub sub-pixels may be identical to an area of an emission area of each of the first main sub-pixels.

According to some embodiments, the pixel electrode of any one sub sub-pixel from among the plurality of sub sub-pixels may be electrically connected to a pixel electrode of a first main sub-pixel adjacent to the any one sub sub-pixel.

According to some embodiments, a display device may include a display panel including a first area in which a plurality of main sub-pixels are arranged and a second area in which a plurality of auxiliary sub-pixels are arranged, and a component under the display panel and corresponding to the second area, wherein the display panel may include a substrate including the first area and the second area, the plurality of main sub-pixels arranged in the first area, the plurality of auxiliary sub-pixels arranged in the second area, and a plurality of sub sub-pixels arranged adjacent to a first boundary of the second area in a first direction, the plurality of auxiliary sub-pixels may include a plurality of first auxiliary sub-pixel arranged in a first auxiliary line that is a virtual line extending in the first direction, and a plurality of second auxiliary sub-pixel and a plurality of third auxiliary sub-pixels alternately arranged in a second auxiliary line that is a virtual line parallel to the first auxiliary line, and each of the plurality of sub sub-pixels may be between the second auxiliary sub-pixel and the third auxiliary sub-pixel neighboring each other in the first direction.

According to some embodiments, the first auxiliary sub-pixel, the second auxiliary sub-pixel, the first auxiliary sub-pixel, and the third auxiliary sub-pixel may be repeatedly arranged in a third auxiliary line that is a virtual line extending in a second direction orthogonal to the first direction.

According to some embodiments, centers of the plurality of sub sub-pixels may be arranged in the second auxiliary line.

According to some embodiments, the plurality of auxiliary sub-pixels and the first auxiliary sub-pixels may emit light of a same color.

According to some embodiments, a pixel electrode of any one sub sub-pixel from among the plurality of auxiliary sub-pixels may be electrically connected to a pixel electrode of a first auxiliary sub-pixel adjacent to the any one sub sub-pixel.

According to some embodiments, the plurality of main sub-pixels may include a plurality of first main sub-pixels arranged in a first main line that is a virtual line extending in the first direction, and the plurality of second main sub-pixels and the plurality of third main sub-pixels alternately arranged in a second main line that is a virtual line parallel to the first main line, and centers of the first main sub-pixels arranged in the first main line, and centers of the second main sub-pixels and the third main sub-pixels arranged in the second main line, are arranged in a zig-zag manner.

According to some embodiments, the second auxiliary line and the first main line may neighbor each other with the first boundary therebetween.

According to some embodiments, the plurality of sub sub-pixels and the first main sub-pixels may emit light of a same color.

According to some embodiments, an area of an emission area of each of the plurality of sub sub-pixels may be identical to an area of an emission area of each of the first main sub-pixels.

According to some embodiments, the pixel electrode of any one sub sub-pixel from among the plurality of sub sub-pixels may be electrically connected to a pixel electrode of a first main sub-pixel adjacent to the any one sub sub-pixel.

According to some embodiments, a display device may include a display panel including a first area in which a plurality of main sub-pixels are arranged and a second area in which a plurality of auxiliary sub-pixels are arranged, and a component under the display panel and corresponding to the second area, wherein the display panel may include a substrate including the first area and the second area, the plurality of main sub-pixels arranged in the first area, the plurality of auxiliary sub-pixels arranged in the second area, and the plurality of sub sub-pixels arranged adjacent to a first boundary between the first area and the second area, the sub sub-pixels and some of the plurality of main sub-pixels may be connected to a same pixel circuit, and a pixel electrode of the sub sub-pixel and a pixel electrode of the main sub-pixel may be connected to each other through a pixel connection wiring.

According to some embodiments, a pixel circuit of a main sub-pixel that is arranged in the first area and not connected to the sub sub-pixel may be different from a pixel circuit of a main sub-pixel connected to the sub sub-pixel.

Aspects, features, and characteristics other than the descriptions will be clearly understood from the following drawings, claims, and detailed descriptions.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating a display device according to some embodiments;

FIGS. 2A and 2B are cross-sectional views each schematically illustrating a portion of a cross-section of a display device according to some embodiments;

FIG. 3 is a top plan view schematically illustrating a display panel which may be included in the display device shown in FIG. 1, according to some embodiments;

FIG. 4 is top plan view schematically illustrating a display panel which may be included in the display device shown in FIG. 1, according to some embodiments;

FIG. 5 is a cross-sectional view schematically illustrating a portion of a cross-sectional view of a display device according to some embodiments;

FIGS. 6 to 8 are top plan views each schematically illustrating a portion of a display panel according to some embodiments;

FIGS. 9 to 10 are equivalent circuit diagrams of a pixel which may be included in a display panel according to some embodiments;

FIGS. 11A, 11B, and 12 are top plan views schematically illustrating an arrangement of pixels of a display panel according to some embodiments;

FIGS. 13A, 13B, and 14 are top plan views each schematically illustrating an arrangement of pixels of a display panel according to some embodiments;

FIG. 15 is a cross-sectional view schematically illustrating a portion of a display panel according to some embodiments;

FIGS. 16 and 17 are cross-sectional views each schematically illustrating a portion of a display panel according to some embodiments; and

FIGS. 18 and 19 are cross-sectional views each schematically illustrating a portion of a display panel according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

In the present specification, terms such as “first,” “second” are not used in a limited sense but used to distinguish one component from others.

In the present specification, unless explicitly intended otherwise, singular forms also encompass plural forms.

In the present specification, terms such as “comprise,” “include,” and “have” indicate the presence of features or components disclosed in the specification, and are not to preclude the possibility of the addition of one or more other features or components.

In the present specification, when a portion such as a film, an area, or a component is on or above another portion, the portion may be directly on the other portion, or alternatively, another film, area, component and the like may be between the portion and the other portion.

In the present specification, it will be understood that when a film, an area, or a component is referred to as being “connected” to another film, area, or component, the film, area, or component may be “directly” connected to the other film, area, or component or connected to the other film, area, or component with an intervening film, area, or component therebetween. For example, in the present specification, when a film, an area, or a component is referred to as being electrically connected to another film, area, or component, it will be understood that the film, area, or component may be electrically connected in a direct manner to the other film, area, or the component, and/or electrically connected in an indirect manner to the other film, area, or the component, with a film, area, or component therebetween.

In the present specification, “A and/or B” indicates A, B, or A and B. “At least one of A and B” indicates A, B, or A and B.

In the present specification, the x axis, the y axis, and the z axis are not limited to three axes on an orthogonal coordinate system, and may be interpreted as having a wider meaning including the three axes on the orthogonal coordinate system. For example, the x axis, the y axis, and the x axis may be orthogonal to one another, but may also refer to different directions that are not orthogonal to one another.

In the present specification, when an embodiment may be differently implemented, a specific order may be performed different from a described order. For example, two processes successively described may be substantially simultaneously performed, or may be performed in an order opposite to the described order.

For convenience of explanation, sizes of components in the drawings may be exaggerated or reduced. For example, sizes and thicknesses of components shown in the drawings are arbitrarily shown for convenience of explanation, and therefore, the disclosure is not necessarily limited to the drawing.

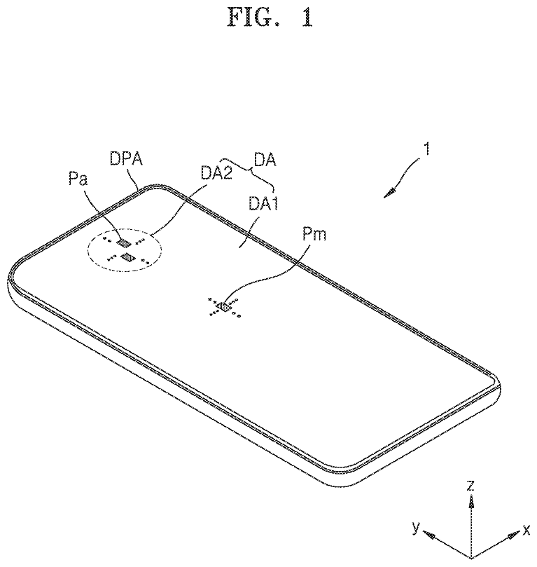

FIG. 1 is a perspective view schematically illustrating a display device 1 according to some embodiments.

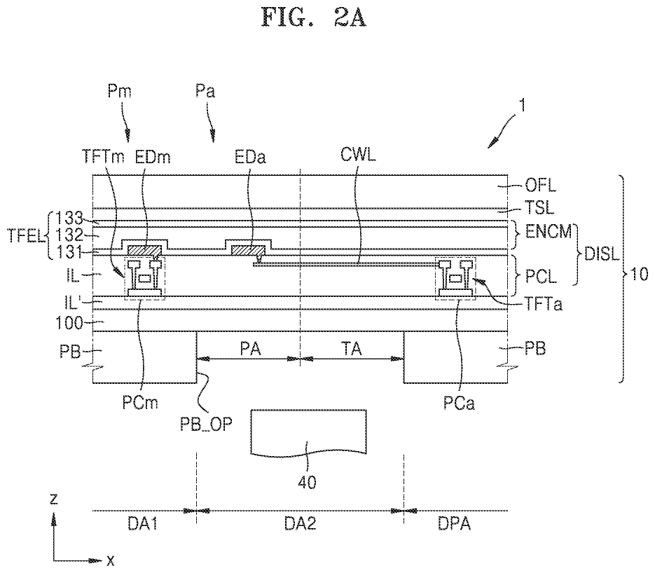

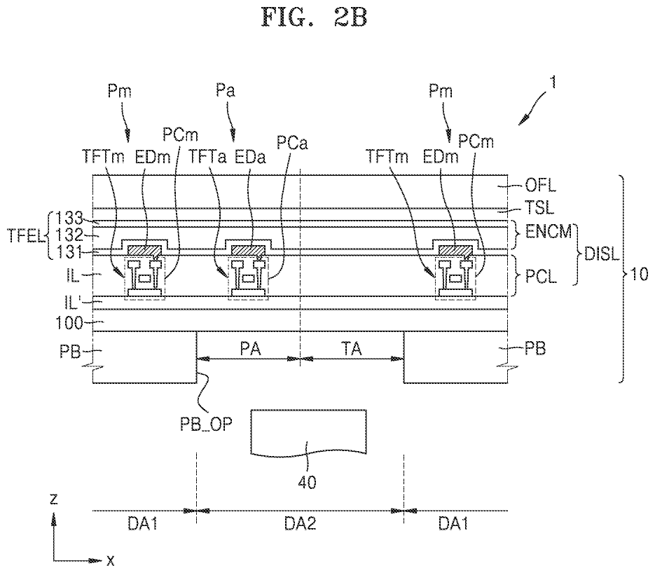

Referring to FIG. 1, the display device 1 includes a display area DA and a peripheral area DPA outside the display area DA. The display area DA may include a first display area DA1 and a second display area DA2. The first display area DA1 may at least partially surround the second display area DA2. The first display area DA1 may include a main display area, and the second display area DA2 may include a component area in which a component 40 (see FIG. 2a) is arranged, and may also include an auxiliary display area. The first display area DA1 and the second display area DA2 may separately display images, or may display images together. The peripheral area DPA may include a kind of non-display area, in which display elements are not arranged. The display area DA may be entirely surrounded by the peripheral area DPA.

FIG. 1 illustrates that one second display area DA2, in which the component 40 is arranged, is in the first display area DA1. According to some embodiments, the display device 1 may have two or more second display areas DA2, and the second display areas DA2 may have different shapes and sizes. Seen in a direction approximately perpendicular to a top surface of the display device 1, a shape of the second display area DA2 may include various shapes such as a circle shape, an elliptical shape, a polygonal shape such as a square shape, a star shape, a diamond shape, or the like. Although FIG. 1 illustrates that the second display area DA2 is arranged in the middle of top (a +y direction) of the first display area DA1 that is almost square when seen in the direction approximately perpendicular to the top surface of the display device 1, the second display area DA2 may be arranged at a side of the first display area DA1 having a square shape, for example, a right-upper side or a left-upper side.

The display device 1 may provide images using a plurality of pixels. Each pixel may include sub-pixels capable of displaying red, green, and blue colors. Each pixel may include a group of sub-pixels.

Each sub-pixel may be implemented as an emission area of a display element. The display element may include a pixel electrode (an anode), a counter electrode (a cathode), and an emission layer between the pixel electrode and the counter electrode, and the emission area may be defined as an area in which the emission layer emits light. According to some embodiments, the emission area may be defined as an opening area of a pixel defining film, which covers a boundary of the pixel electrode and exposes a center portion of the pixel electrode. Likewise, the sub-pixel may be defined as an opening area of the pixel defining film.

The emission layer may substantially include organic materials capable of displaying red, green, and blue colors. The emission layer may include an emission area, in which light is actually emitted, and a non-emission area in which light is not emitted, according to an area in which the pixel electrode (the anode) and the counter electrode (the cathode) overlap with each other.

In the present specification, a pixel may be used as a same concept as a sub-pixel. That is, the pixel may be implemented as an emission area of a display element. In some cases, the pixel or the sub-pixel may be used as the same concept as the display element.

The display device 1 may provide images using a plurality of main sub-pixels Pm arranged in the first display area DA1 and a plurality of auxiliary sub-pixels Pa arranged in the second display area DA2.

The plurality of auxiliary sub-pixels Pa may be arranged in the second display area DA2. The plurality of auxiliary sub-pixels Pa may emit light to provide certain images. An image displayed in the second display area DA2 may include an auxiliary image and may have a resolution lower than a resolution of an image displayed in the first display area DA1.

In the second display area DA2, the component 40, which is an electronic element, may be under the display panel. The component 40 may include a camera, which uses an infrared ray, a visible ray or the like, as an imaging device. Alternatively, the component 40 may include a solar battery, a flash, an illuminance sensor, a proximity sensor, or an iris sensor. Alternatively, the component 40 may receive sounds.

In the display panel according to some embodiments and a display device including the same, when light is transmitted through the second display area DA2, a light transmittance may be about at least 10%, at least 25%, at least 40%, at least 50%, at least 85%, or at least 90%.

FIGS. 2A and 2B are cross-sectional views each schematically illustrating a portion of a cross-section of the display device 1 according to some embodiments.

Referring to FIGS. 2A and 2B, the display device 1 may include a display panel 10 and the component 40 overlapping the display panel 10. A cover window protecting the display panel 10 may be further located above the display panel 10.

The display panel 10 may include the second display area DA2, in which the auxiliary sub-pixels Pa are arranged, and the first display area DA1 in which the main sub-pixels Pm are arranged. The component 40 may overlap the second display area DA2. The display panel 10 may include a substrate 100, a display layer DISL above the substrate 100, a touch-screen layer TSL, an optical function layer OFL, and a panel protection member PB located under the substrate 100.

The display layer DISL may include a pixel circuit layer PCL including thin-film transistors (e.g., a main thin-film transistor TFTm and an auxiliary thin-film transistor TFTa), a display element layer including light-emitting elements (i.e., a main display element EDm and an auxiliary display element EDa) as display elements, and an encapsulation member ENCM such as a thin-film encapsulation layer TFEL or an encapsulation substrate. Insulating layers IL and IL's may be arranged between the substrate 100 and the display layer DISL and in the display layer DISL.

The substrate 100 may include an insulating material such as glass, quartz, and a polymer resin. The substrate 100 may include a rigid substrate or a flexible substrate that may be bent, folded, or rolled.

A main pixel circuit PCm and the main display element EDm connected thereto may be arranged in the first display area DA1 of the display panel 10. The main pixel circuit PCm may include at least one thin-film transistor (i.e., the main thin-film transistor TFTm), and may control emission of the main display element EDm. The main sub-pixel Pm may be implemented by emission of the main display element EDm.

The auxiliary display element EDa may be arranged in the second display area DA2 of the display panel 10 to implement the auxiliary sub-pixel Pa. The second display area DA2 includes the auxiliary display area, and a resolution of the second display area DA2 may be less than a resolution of the first display area DA1. That is, the number per unit area of the auxiliary display elements EDa arranged in the second display area DA2 may be smaller than the number per unit area of the main display elements EDm arranged in the first display area DA1.

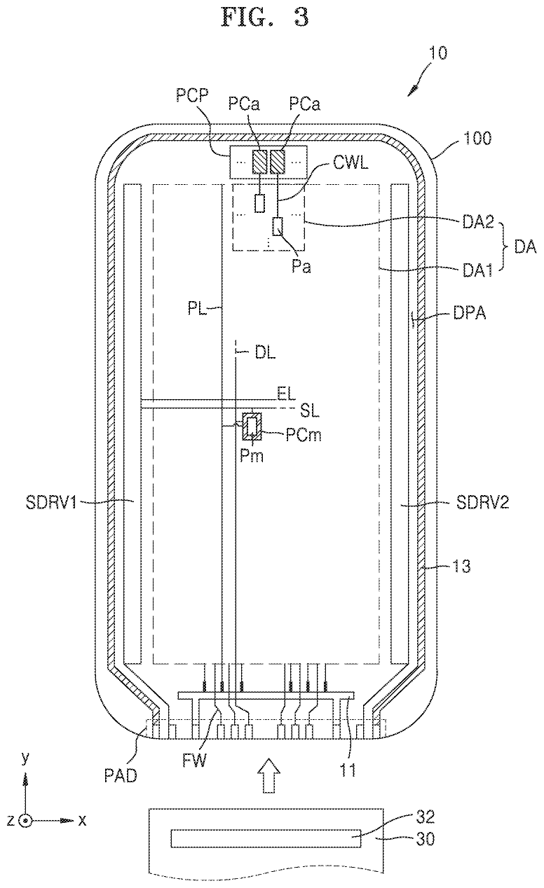

The auxiliary pixel circuit PCa configured to drive the auxiliary display element EDa may be arranged in a pixel circuit part PCP (see FIG. 3) that does not overlap with the auxiliary display element EDa. For example, the pixel circuit part PCP (see FIG. 3) may not be arranged in the second display area DA2 but may be arranged outside the second display area DA2. As shown in FIG. 2A, the auxiliary pixel circuit PCa may not be arranged in the second display area DA2 but may be arranged in the peripheral area DPA. The auxiliary display element EDa and the auxiliary pixel circuit PCa may be electrically connected to each other through a connection wiring CWL.

According to some embodiments, as shown in FIG. 2B, the auxiliary pixel circuit PCa configured to drive the auxiliary display element EDa may be arranged in the second display area DA2. In this case, seen in the direction approximately perpendicular to the top surface of the display device 1, the auxiliary display element EDa and the auxiliary pixel circuit PCa may overlap each other. The second display area DA2 may include a transmission area TA in which the auxiliary display elements EDa are not arranged and a pixel area PA in which the auxiliary display elements EDa are arranged, and the auxiliary pixel circuit PCa may be arranged in the pixel area PA. Various modifications are available, for example, according to some embodiments, the first display area DA1 may include the pixel circuit part PCP (see FIG. 3).

The auxiliary pixel circuit PCa may include at least one thin-film transistor (i.e., the auxiliary thin-film transistor TFTa), and may be electrically connected to the auxiliary display element EDa. The auxiliary pixel circuit PCa may control emission of the auxiliary display element EDa. The auxiliary sub-pixel Pa may be implemented by emission of the auxiliary display element EDa.

In addition, the second display area DA2 may include the transmission area TA, through which light/signals emitted from the component 40 or light/signals incident to the component 40 are transmitted. In the second display area DA2, the transmission area TA may include an area in which the pixel electrode (the anode) of the auxiliary display element EDa is not arranged. The transmission area TA may include an area except the area in which the auxiliary display element EDa emits light. The transmission area TA may include an area between the auxiliary sub-pixels Pa. The transmission area TA may include an area between the auxiliary display elements EDa.

A buffer layer, which may be included in the insulating layer IL and IL′, and an inorganic insulating layer such as a gate insulating layer may be arranged in the transmission area TA. The transmission area TA may include an organic insulating layer that may be included in the insulating layers IL and IL′. The counter electrode (the cathode) may be arranged in the transmission area TA. An inorganic encapsulation layer and/or an organic encapsulation layer of the thin-film encapsulation layer TFEL may be arranged in the transmission area TA. Wirings including a metal and/or a transparent conducting material may be arranged in the transmission area TA. The substrate 100, a polarizer, an adhesive, a window, and the panel protection member PB may be arranged in the transmission area TA.

As the number per unit area of the auxiliary display elements EDa arranged in the second display area DA2 is less than the number per unit of the main display elements EDm arranged in the first display area DA1, the area overlapping the component 40 may have a high transmittance.

The main display element EDm and the auxiliary display element EDa, which are display elements, may be covered with the thin-film encapsulation layer TFEL or an encapsulation substrate. In some embodiments, the thin-film encapsulation layer TFEL may include at least one inorganic encapsulation layer and at least one organic encapsulation layer, as shown in FIGS. 2A and 2B. According to some embodiments, the thin-film encapsulation layer TFEL may include a first inorganic encapsulation layer 133 and a second inorganic encapsulation layer 133, and an organic encapsulation layer 132 therebetween.

The first inorganic encapsulation layer 131 and the second inorganic encapsulation layer 133 may include at least one inorganic insulating material such as silicon oxide (SiOₓ), silicon nitride (SiNₓ), silicon oxynitride (SiON), aluminum oxide (AlO₃), titanium oxide (TiO₂), tantalum oxide (Ta₂O₅), and hafnium oxide (HfO₂), and may be formed by chemical vapor deposition (CVD) and the like. The organic encapsulation layer 132 may include a polymer-based material. The polymer-based material may include a silicon-based resin, an acryl-based resin, an epoxy-based resin, polyimide, polyethylene, and the like.

The first inorganic encapsulation layer 131, the organic encapsulation layer 132, and the second inorganic encapsulation layer 133 may be integrally formed to cover the first display area DA1 and the second display area DA2.

When the main display element EDm and the auxiliary display element EDa, which are the display elements, are encapsulated by the encapsulation substrate, the encapsulation substrate may face the substrate 100 with the display element therebetween. A gap may be between the encapsulation substrate and the display element. The encapsulation substrate may include glass. A sealant including frit and the like is between the substrate 100 and the encapsulation substrate, and the sealant may be in the aforementioned peripheral area DPA. The sealant arranged in the peripheral area DPA may surround the display area DA and may prevent permeation of moisture through side surfaces of the display area DA.

The touch-screen layer TSL may include coordination information according to external inputs, for example, touch events. The touch-screen layer TSL may include a touch electrode and touch wirings connected thereto. The touch-screen layer TSL may sense external outputs by using a self capacitance method or a mutual capacitance method.

The touch-screen layer TSL may be formed on the thin-film encapsulation layer TFEL. Alternatively, the touch-screen layer TSL may be separately formed on a touch substrate and then coupled to the thin-film encapsulation layer TFEL through an adhesive layer such as an optical clear adhesive (OCA). According to some embodiments, the touch-screen layer TSL may be formed directly on the thin-film encapsulation layer TFEL, and in this case, the adhesive layer may not be between the touch screen layer TSL and the thin-film encapsulation layer TFEL.

The optical function layer OFL may include an anti-reflection layer. The anti-reflection layer may reduce the reflectance of light (external light) incident to the display device 1 from outside. In some embodiments, the optical function layer OFL may include a polarization film. In some embodiments, the optical function layer OFL may include a filter plate including a black matrix and/or color filters. The black matrix or the color filters may be omitted.

The panel protection member PB may be attached under the substrate 100 to support and protect the substrate 100. The panel protection member PB may include an opening PB_OP corresponding to the second display area DA2. As the panel protection member PB includes the opening PB_OP, the transmittance of the second display area DA2 may be improved. The panel protection member PB may include polyethyleneterephthalate (PET) or polyimide (PI).

An area of the second display area DA2 may be greater than an area in which the component 40 is arranged. Accordingly, an area of the opening PB_OP provided in the panel protection member PB may not be identical to the area of the second display area DA2. However, the embodiments are not limited thereto. For example, the panel protection member PB may not include the opening PB_OP and may be continuously arranged to correspond to the second display area DA2.

In addition, a plurality of the components 40 may be arranged in the second display area DA2. The plurality of components 40 may have different functions. For example, a plurality of components 40 may include at least two of a camera (an imaging device), a solar battery, a flash, a proximity sensor, an illuminance sensor, and an iris sensor.

FIG. 3 is a top plan view schematically illustrating the display panel which may be included in the display device shown in FIG. 1, according to some embodiments.

Referring to FIG. 3, elements included in the display panel 10 are located on the substrate 100. The substrate 100 includes the display area DA and the peripheral area DPA surrounding the display area DA. The display area DA includes the first display area DA1 in which a main image is displayed and the second display area DA2 in which an auxiliary image is displayed. The auxiliary image and the main image may together form an entire image, and the auxiliary image may include an image independent from the main image.

A plurality of the main sub-pixels Pm are arranged in the first display area DA1. The main sub-pixels Pm may each be implemented as a display element such as an organic light-emitting diode OLED. The main pixel circuit PCm configured to drive the main sub-pixel Pm may be arranged in the first display area DA1, and may overlap the main sub-pixel Pm. Each main sub-pixel Pm may emit light having, for example, red, green, blue, or white colors. The first display area DA1 may be covered by an encapsulation member and protected from external air or moisture.

The second display area DA2 may be on a side of the first display area DA1 or may be arranged inside the display area DA and surrounded by the first display area DA1. The plurality of auxiliary sub-pixels Pa are arranged in the second display area DA2. The plurality of auxiliary sub-pixel Pa may each be implemented by a display element such as an organic light-emitting diode. The auxiliary pixel circuit PCa configured to drive the auxiliary sub-pixel Pa may be arranged in the peripheral area DPA adjacent to the second display area DA2. For example, when the second display area DA2 is arranged at top of the display area DA, the pixel circuit portion PCP in which the auxiliary pixel circuit PCa is located may be arranged at top of the peripheral area DPA. In other embodiments, the auxiliary pixel circuit PCa may also be arranged in the peripheral areas DPA at two sides of the top of the display area DA. The first display area DA1 may be between the pixel circuit portion PCP in which the auxiliary pixel circuit PCa is located and the second display area DA2 in which the auxiliary pixel circuit PCa is located. Display elements implementing the auxiliary pixel circuit PCa and the auxiliary sub-pixel Pa may be connected to each other by the connection wirings CWL. Each auxiliary sub-pixel Pa may emit light having, for example, red, green, blue, or white colors. The second display area DA2 may be covered by the encapsulation member and protected from external air or moisture.

The resolution of the second display area DA2 may be about ½, ⅜, ⅓, ¼, 2/9, ⅛, 1/9, 1/16, and the like of the resolution of the first display area DA1. For example, the resolution of the first display area DA1 may be about at least 400 ppi, and the resolution of the second display area DA2 may be about 200 ppi or about 100 ppi.

Each of the pixel circuits PCm and PCa configured to drive the sub-pixels Pm and Pa may be electrically connected to outskirt circuits arranged in the peripheral area DPA. A first scan drive circuit SDRV1, a second scan drive circuit SDRV2, a pad PAD, a driving voltage supply line 11, and a common voltage supply line 13 may be arranged in the peripheral area DPA.

The first scan drive circuit SDRV1 may apply a scan signal, through a scan line SL, to each of the main pixel circuits PCm configured to drive the main sub-pixels Pm. The first scan drive circuit SDRV1 may apply an emission control signal to each pixel circuit through an emission control line EL. The second scan drive circuit SDRV2 may be on a side opposite to the first scan drive circuit SDRV1 with reference to the first display area DA1, and may be approximately parallel to the first scan drive circuit SDRV1. Some of the pixel circuits of the main sub-pixels Pm in the first display area DA1 may be electrically connected to the first scan drive circuit SDRV1, and others may be electrically connected to the second scan drive circuit SDRV2.

The pad PAD may be at a side of the substrate 100. The pad PAD is exposed without being covered by an insulating layer, and is connected to a display circuit board 30. A display driver 32 may be located on the display circuit board 30.

The display driver 32 may generate a control signal to be transmitted to the first scan drive circuit SDRV1 and the second scan drive circuit SDRV2. The display driver 32 may generate a data signal, and the data signal that has been generated may be transmitted to the main pixel circuits PCm through a fan-out wiring FW and a data line DL connected to the fan-out wiring FW.

The display driver 320 may supply a driving voltage ELVDD to a driving voltage supply line 11, and may supply a common voltage ELVSS to a common voltage supply line 13. The driving voltage ELVDD may be applied to pixel circuits of the sub-pixels (i.e., the main sub-pixels Pm and the auxiliary sub-pixels Pa) through the driving voltage line PL connected to the driving voltage supply line 11, and the common voltage ELVSs may be connected to the common voltage supply line 13 and applied to the counter electrode of the display element.

The driving voltage 11 may be provided under the first display area DA1 and extend in the x direction. The common voltage supply line 13 may have a loop shape in which a side is open, and may partially surround the first display area DA1.

Although FIG. 3 illustrates that there is only one second display area DA2, the second display area DA2 may be provided as a plurality of second display areas DA2. In this case, the plurality of second display areas DA2 may be apart from each other, a first camera may be arranged to correspond to one of the second display areas DA2, and a second camera may be arranged to correspond to another one of the second display areas DA2. Alternatively, a camera may be arranged to correspond to one of the second display areas DA2, and an infrared ray sensor may be arranged to correspond to another one of the second display areas DA2. The plurality of second display areas DA2 may have different shapes and sizes.

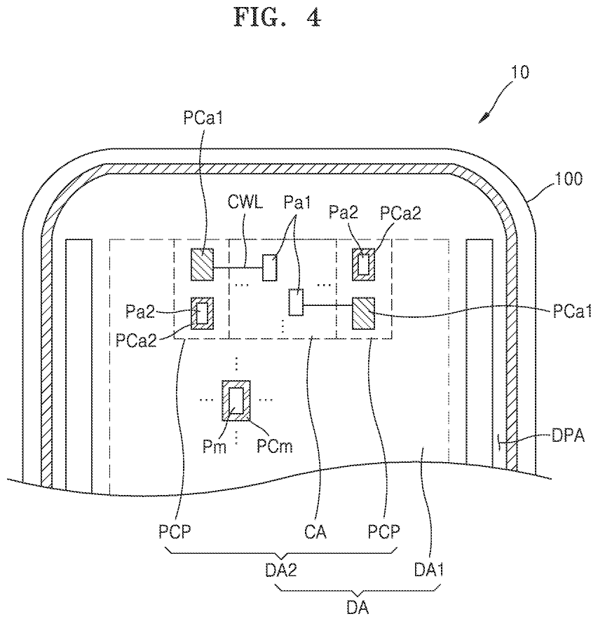

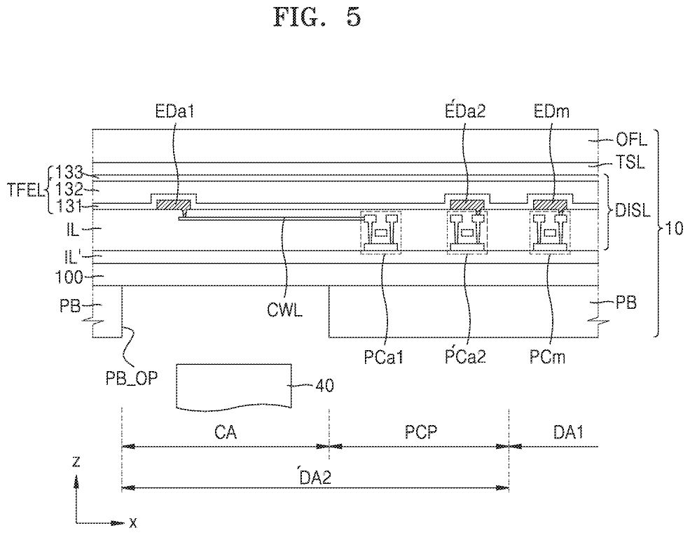

FIG. 4 is a top plan view schematically illustrating a display panel that may be included in the display device shown in FIG. 1; and FIG. 5 is a cross-sectional view schematically illustrating a portion of a cross-section of the display device shown in FIG. 4. In FIGS. 4 and 5, the same reference numerals as those of FIGS. 2A, 2B, and 3 indicate same members, and therefore, description thereof will not be repeatedly given.

Referring to FIGS. 4 and 5, the display area DA of the substrate 100 includes the first display area DA1 and the second display area DA2. The second display area DA2 may include a component area CA overlapping the component 40 and a pixel circuit part PCP arranged outside the component area CA.

The first display area DA1 may include an area in which a main image is displayed. The second display area DA2 may include an area in which an auxiliary image is displayed. The auxiliary image and the main image may together form an entire image, and the auxiliary image may include an image independent from the main image.

The pixel circuit part PCP may be arranged on at least one side of the component area CA. Although FIG. 4 illustrates that the pixel circuit part PCP is arranged on the left and right of the component area CA, the embodiments are not limited thereto. The pixel circuit part PCP may be variously modified, for example, the pixel circuit part PCP may be arranged above/under the component area CA, or may surround the component area CA.

The auxiliary sub-pixels arranged in the second display area DA2 may include a first auxiliary sub-pixel Pa1 and a second auxiliary sub-pixel Pa2. A plurality of the first auxiliary sub-pixels Pa1 are arranged in the component area CA, and a plurality of the second auxiliary sub-pixels Pa2 are arranged in the pixel circuit part PCP. The first auxiliary sub-pixel Pa1 and the second auxiliary sub-pixel Pa2 may each be implemented as display elements such as an organic light-emitting diode (OLED). A second auxiliary pixel circuit PCa2 configured to drive the second auxiliary sub-pixel Pa2 is arranged in the pixel circuit part PCP, and the second auxiliary sub-pixel Pa2 may overlap the second auxiliary pixel circuit PCa2. Each of the second auxiliary sub-pixels Pa2 may emit, for example, red, green, blue, or white light.

A first auxiliary pixel circuit PCa1 configured to drive the first auxiliary sub-pixel Pa1 of the component area CA is arranged in the pixel circuit part PCP. The first auxiliary pixel circuits PCa1 and the second auxiliary pixel circuits PCa2 may be alternately arranged in the pixel circuit part PCP. The first auxiliary pixel circuit PCa1 and the auxiliary display element EDa, which is configured to implement the first auxiliary sub-pixel Pa1, may be connected to each other by the connection wiring CWL.

The pixel circuit part PCP may have a same resolution as a resolution of the component area CA. Alternatively, the resolution of the pixel circuit part PCP may be higher than the resolution of the component area CA and lower than a resolution of the first display area DA1.

For example, the resolution of the pixel circuit part PCP may be about ½, ⅜, ⅓, ¼, 2/9, ⅛, 1/9, 1/16 and the like of the resolution of the first display area DA1. For example, the resolution of the first display area DA1 may be at least about 400 ppi, and the resolutions of the component area CA and the pixel circuit part PCP may be about 200 ppi or 100 ppi.

In some embodiments, the main pixel circuit PCm, the first auxiliary pixel circuit PCa1, and the second auxiliary pixel circuit PCa2 may be identical to one another. However, the embodiments are not limited thereto. The embodiments may be variously modified, for example, the main pixel circuit PCm, the first auxiliary pixel circuit PCa1, and the second auxiliary pixel circuit PCa2 may be different from one another.

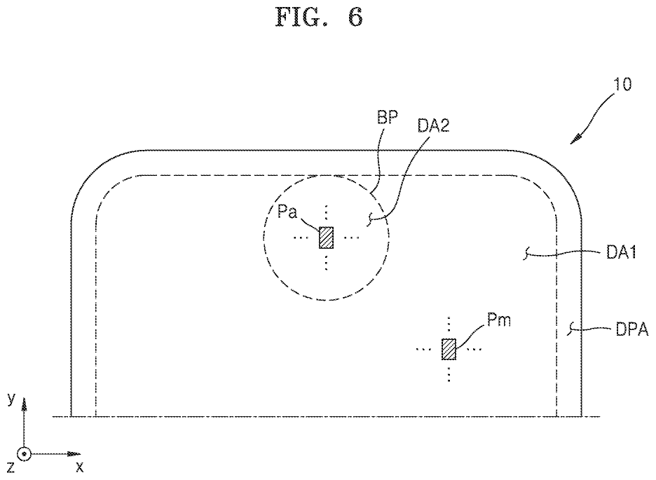

FIGS. 6 to 8 are top plan views each schematically illustrating a portion of a display panel according to an embodiment; FIGS. 6 to 8 illustrate various arrangements in the second display area DA2.

Referring to FIG. 6, the second display area DA2 is approximately circular, and a circumstance BP thereof contacts the first display area DA1. Hereinafter, in the present specification, when it is referred that a ‘circumference’ or a ‘side’ of a first area and a second area that are distinguished from each other are in contact, it may indicate that the first area and the second area are in contact having the ‘circumstance’ or ‘side’ as a boundary.

In an enlarged view of the circumstance BP of the second display area DA2, a curve of the circumstance BP may include an arrangement in which a boundary extending in the first direction (e.g., the x direction) and a boundary extending in the second direction (e.g., the y direction) are alternately arranged.

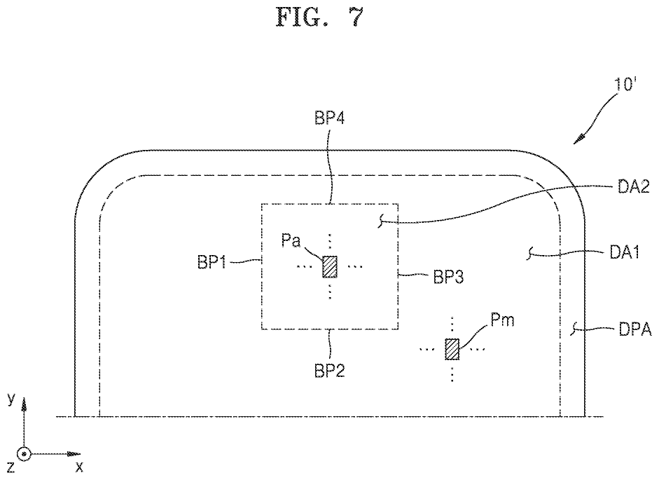

Referring to FIG. 7, the second display area DA2 is approximately square, and all sides thereof contact the first display area DA1. Four sides of the second display area DA2 may contact the first display area DA1. That is, the second display area DA2 may be surrounded by the first display area DA1 and located in the first display area DA1. The second display area DA2 and the first display area DA1 shown in FIG. 3 may contact each other at a first boundary BP1, a second boundary BP2, a third boundary BP3, and a fourth boundary BP4. According to some embodiments, at least one side of the second display area DA2 may contact the peripheral area DPA.

In FIG. 7, the first boundary BP1 and the third boundary BP3 may extend in the second direction (e.g., the y direction) and be parallel to each other, and the second boundary BP2 and the fourth boundary BP4 may extend in the first direction (e.g., the x direction) and be parallel to each other. In this case, the first direction (e.g., the x direction) and the second direction (e.g., the y direction) may cross each other. That is, the first direction (e.g., the x direction) and the second direction (e.g., the y direction) may be orthogonal to each other.

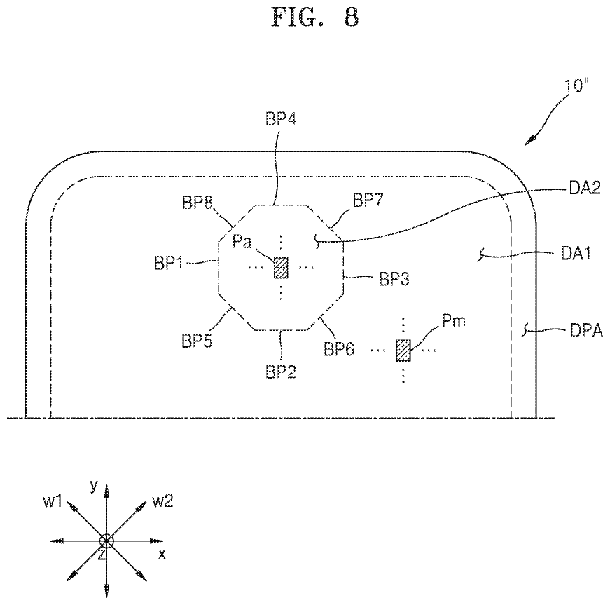

Referring to FIG. 8, the second display area DA2 has an approximately octagonal shape, and all sides thereof contact the first display area DA1. However, according to some embodiments, at least one side of the second display area DA2 may contact the peripheral area DPA.

The second display area DA2 may contact the first display area DA1 on eight sides. That is, the second display area DA2 may be surrounded by the first display area DA1 and located in the first display area DA1. The second display area DA2 and the first display area DA1 shown in FIG. 4 may contact each other at first to eighth boundaries BP1 to BP8.

According to some embodiments, the first boundary BP1 and the third boundary BP3 may extend in the second direction (e.g., the y direction) and be parallel to each other, and the second boundary BP2 and the fourth boundary BP4 may extend in the first direction (e.g., the x direction) and be parallel to each other. Here, the first boundary BP1 and the second boundary BP2 may cross each other. That is, the first boundary BP1 and the second boundary BP2 may be orthogonal to each other. In addition, the fifth boundary BP5 and the seventh boundary BP7 may extend in a first oblique line direction (e.g., a w1 direction) and be parallel to each other, and the sixth boundary BP6 and the eighth boundary BP8 may extend in a second oblique line direction (e.g., a w2 direction) and be parallel to each other. In this case, the first oblique line direction (e.g., the w1 direction) and the second oblique line direction (e.g., the w2 direction) may cross each other. That is, the first oblique line direction (e.g., the w1 direction) and the second oblique line direction (e.g., the w2 direction) may be orthogonal to each other. In an enlarged view of the fifth to eighth boundaries BP5 to BP8 in pixel units, boundaries extending in the first direction (e.g., the x direction) and boundaries extending in the second direction (e.g., the y direction) may be alternately arranged and form the first oblique line direction (e.g., the w1 direction) or the second oblique line direction (e.g., the w2 direction). The second display area DA2 may also have an oval shape, a polygonal shape, or an amorphous shape.

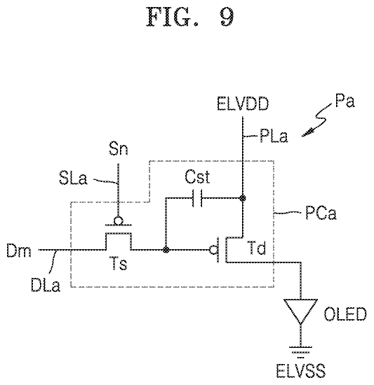

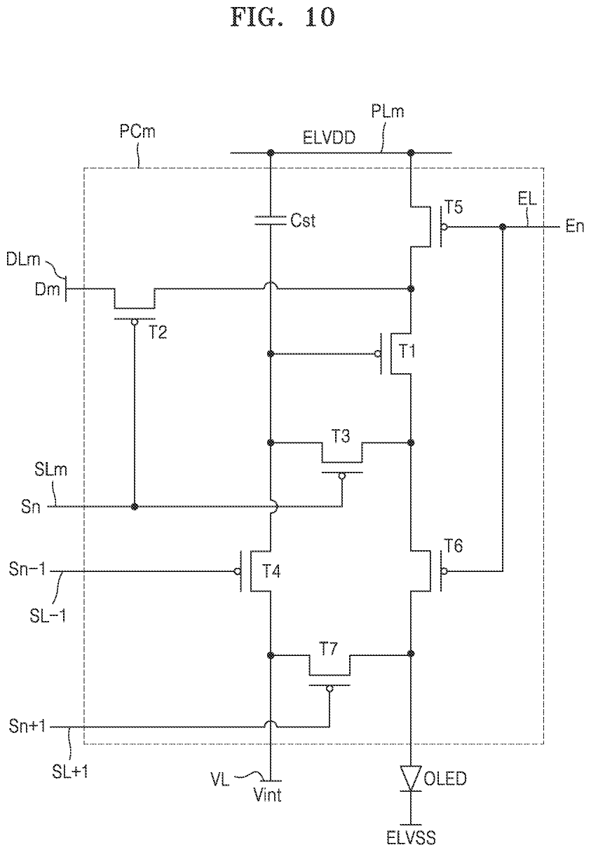

FIGS. 9 to 10 are equivalent circuit diagrams of a pixel which may be included in a display panel according to an embodiment;

Referring to FIGS. 9 and 10, the main sub-pixel Pm includes: the main sub-pixel Pm and an organic light-emitting diode OLED as a display element connected to the main sub-pixel Pm; and the auxiliary sub-pixel Pa includes the auxiliary pixel circuit PCa and an organic light-emitting diode OLED as a display element connected to the auxiliary pixel circuit PCa. Although FIGS. 9 and 10 illustrate that the auxiliary sub-pixel Pa includes the auxiliary pixel circuit PCa shown in FIG. 9 and the main sub-pixel Pm includes the main pixel circuit PCm shown in FIG. 10, the embodiments are not limited thereto. According to some embodiments, the sub-pixels (i.e., the main sub-pixel Pm and the auxiliary sub-pixel Pa) may include at least one of the pixel circuits (i.e., the main pixel circuit PCm or the auxiliary pixel circuit PCa) shown in FIG. 9 or FIG. 10. For example, both the main sub-pixel Pm and the auxiliary sub-pixel Pa may include the pixel circuit (i.e., the main pixel circuit PCm) shown in FIG. 10.

The auxiliary pixel circuit PCa shown in FIG. 9 includes a driving thin-film transistor Td, a switching thin-film transistor Ts, and a storage capacitor Cst. The switching thin-film transistor Ts is connected to an auxiliary scan line SLa and an auxiliary data line DLa, and transmits a data signal Dm input through the auxiliary data line DLa to the driving thin-film transistor Td, in response to a scan signal Sn input through the auxiliary scan line SLa.

The storage capacitor Cst is connected to the switching thin-film transistor Ts and an auxiliary driving voltage line PLa, and stores a voltage corresponding to a difference between a voltage transmitted from the switching thin-film transistor Ts and a driving voltage ELVDD provided to the auxiliary driving voltage line PLa.

The driving thin-film transistor Td is connected to the auxiliary driving voltage line PLa and the storage capacitor Cst, and may control a driving current flowing from the auxiliary driving voltage line PLa through the organic light-emitting diode OLED, to correspond to a value of the voltage stored in the storage capacitor Cst. The organic light-emitting diode OLED may emit, by the driving current, light having a certain luminance.

Although FIG. 9 illustrates that the auxiliary pixel circuit PCa includes two thin-film transistors and one storage capacitor, the embodiments are not limited thereto. According to some embodiments, as shown in FIG. 10 to be described later, the auxiliary pixel circuit PCa may include seven thin-film transistors and one storage capacitor. According to some embodiments, the auxiliary pixel circuit PCa may include two or more other storage capacitors.

Referring to FIG. 10, the main pixel circuit PCm may include a driving thin-film transistor T1, a switching thin-film transistor T2, a compensating thin-film transistor T3, a first initialization thin-film transistor T4, an operation control thin-film transistor T5, an emission control thin-film transistor T6, and a second initialization thin-film transistor T7.

Although FIG. 10 illustrates that each of the main pixel circuits PCm includes (main) signal lines (i.e., a main scan line SLm, a previous scan line SL−1, a next scan line SL+1, an emission control line EL, a main data line DLm), a (main) initialization voltage line VL, and a (main) driving voltage line PL, the embodiments are not limited thereto. According to some embodiments, at least one of the (main) signal lines (i.e. the main scan line SLm, the previous scan line SL−1, the next scan line SL+1, the emission control line EL, the main data line DLm) and/or the (main) initialization voltage line VL) may be shared by neighboring pixel circuits.

A drain electrode of the driving thin-film transistor T1 may be electrically connected to the organic light-emitting diode OLED via the emission control thin-film transistor T6. The driving thin-film transistor T1 receives a data signal Dm in response to a switching operation of the switching thin-film transistor T2, and provides the driving current to the organic light-emitting diode OLED.

A gate electrode of the switching thin-film transistor T2 is connected to a main scan line SLm, and a source electrode of the switching thin-film transistor T2 is connected to a main data line DLm. A drain electrode of the switching thin-film transistor T2 may be connected to a source electrode of the driving thin-film transistor T1, and at the same time, may be connected to a main driving voltage line PLm via the operation control thin-film transistor T5.

The switching thin-film transistor T2 is turned on in response to the scan signal Sn delivered through the main scan line SLm and performs a switching operation to transmit the data signal Dm, which is transmitted from the main data line DLm, to the source electrode of the driving thin-film transistor T1.

A gate electrode of the compensating thin-film transistor T3 may be connected to the main scan line SLm. A source electrode of the compensating thin-film transistor T3 may be connected to the drain electrode of the driving thin-film transistor T1, and at the same time, may be connected to a pixel electrode of the organic light-emitting diode via the emission control thin-film transistor T6. A drain electrode of the compensating thin-film transistor T3 may be connected to any one electrode of the storage capacitor Cst, a source electrode of the first initialization thin-film transistor T4, and a gate electrode of the driving thin-film transistor T1. The compensating thin-film transistor T3 is turned on in response to the scan signal Sn delivered through the main scan line SLm, and connects the gate electrode and the drain electrode of the driving thin-film transistor T1 to each other, to thereby have the driving thin-film transistor T1 diode-connected.

A gate electrode of the first initialization thin-film transistor T4 may be connected to the previous scan line SL−1. A drain electrode of the first initialization thin-film transistor T4 may be connected to the initialization voltage line VL. The source electrode of the first initialization thin-film transistor T4 may be connected to any one electrode of the storage capacitor Cst, the drain electrode of the compensating thin-film transistor T3, and the gate electrode of the driving thin-film transistor T1. The first initialization thin-film transistor T4 may be turned on in response to a previous scan signal Sn−1 transmitted through the previous scan line SL−1, may transmit an initialization voltage Vint to the gate electrode of the driving thin-film transistor T1, thereby performing an initialization operation to initialize a voltage of the gate electrode of the driving thin-film transistor T1.

A gate electrode of the operation control thin-film transistor T5 may be connected to the emission control line EL. A source electrode of the operation control thin-film transistor T5 may be connected to the main driving voltage line PLm. A drain electrode of the operation control thin-film transistor T5 is connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and a source electrode of the compensating thin-film transistor T3. A drain electrode of the emission control thin-film transistor T6 may be electrically connected to a pixel electrode of the organic light-emitting diode OLED. The operation control thin-film transistor T5 and the emission control thin-film transistor T6 are simultaneously turned on in response to an emission control signal En transmitted through the emission control line EL, and therefore, the driving voltage ELVDD is transmitted to the organic light-emitting diode OLED, and the driving current flows through the organic light-emitting diode OLED.

A gate electrode of the second initialization thin-film transistor T7 may be connected to the next scan line SL+1. A source electrode of the second initialization thin-film transistor T7 may be connected to the pixel electrode of the organic light-emitting diode OLED. A drain electrode of the second initialization thin-film transistor T7 may be connected to the initialization voltage line VL. The second initialization thin-film transistor T7 may be turned on in response to a next scan signal Sn+1 transmitted through the next scan line SL+1 and initialize the pixel electrode of the organic light-emitting diode OLED.

Although FIG. 10 illustrates that the first initialization thin-film transistor T4 and the second initialization thin-film transistor T7 are respectively connected to the previous scan line SL−1 and the next scan line SL+1, the embodiments are not limited thereto. According to some embodiments, both the first initialization thin-film transistor T4 and the second initialization thin-film transistor T7 may be connected to the previous scan line SL−1 and be driven in response to the previous scan signal Sn−1.

Another electrode of the storage capacitor Cst may be connected to the main driving voltage line PLm. Any one electrode of the storage capacitor Cst may be connected to the gate electrode of the driving thin-film transistor T1, the drain electrode of the compensating thin-film transistor T3, and the source electrode of the first initialization thin-film transistor T4.

A common voltage ELVSS is provided to the counter electrode (e.g., the cathode) of the organic light-emitting diode OLED. The organic light-emitting diode OLED may emit light by receiving the driving current from the driving thin-film transistor T1.

The pixel circuits (i.e., the main pixel circuit PCm and the auxiliary pixel circuit PCa) provided according to some embodiments are not limited to the number and circuit design of the thin-film transistors and storage capacitors described with reference to FIGS. 9 and 10, and the number and circuit design may be variously modified.

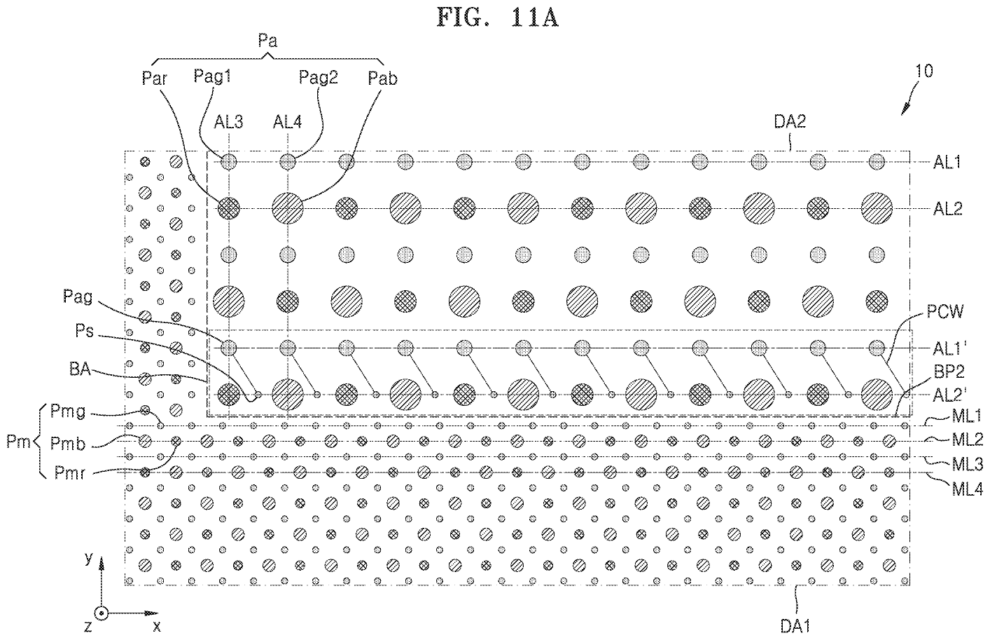

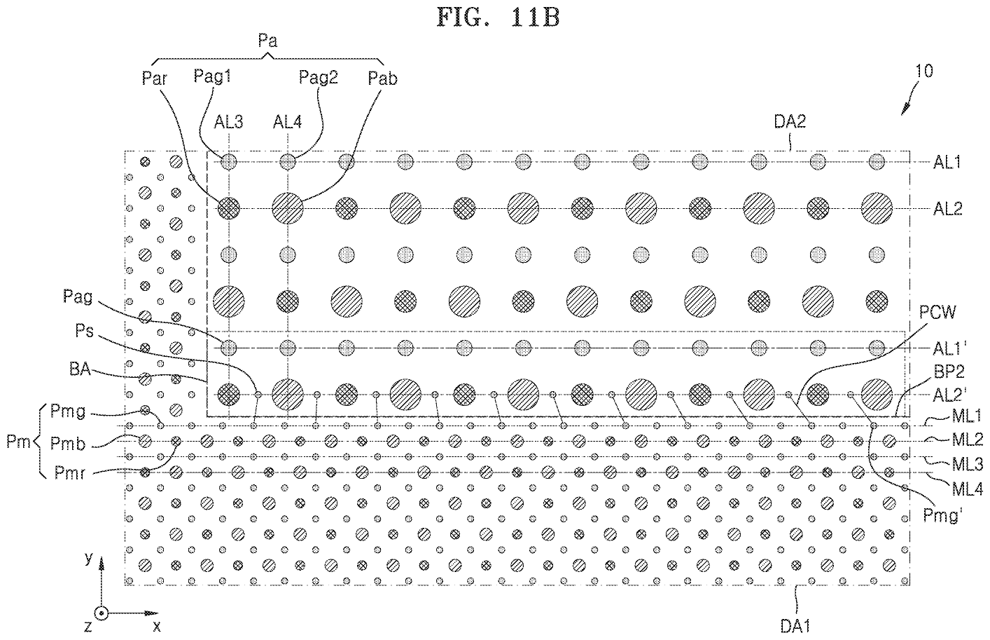

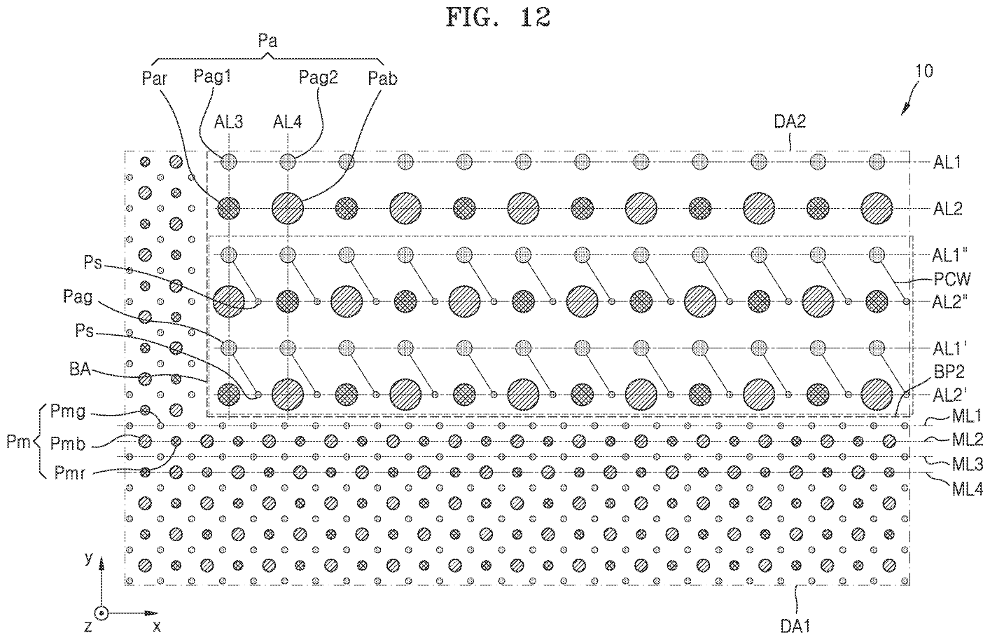

FIGS. 11A, 11B, and 12 are top plan views each schematically illustrating an arrangement of pixels of the display panel according to some embodiments. FIGS. 11A, 11B, and 12 are enlarged views of the display panel shown in FIG. 7 and illustrate a portion of each of the first display area DA1 and the second display area DA2 adjacent to the second boundary BP2.

Referring to FIGS. 11A, 11B, and 12, the plurality of main sub-pixels Pm may be arranged in the first display area DA1. In the present specification, a sub-pixel, which is a smallest unit configured to implement images, includes an emission area configured to emit light by display elements. When an organic light-emitting diode is adopted as a display element, the emission area may be defined by an opening of a pixel defining film. Each of the plurality of main sub-pixels Pm may emit any one of red, green, blue, and white light.

According to some embodiments, the main sub-pixels Pm arranged in the first display area DA1 may include a plurality of first main sub-pixels Pmg, a plurality of second main sub-pixels Pmr, and a plurality of third main sub-pixels Pmb. The first main sub-pixel Pmg may emit green light, the second main sub-pixel Pmr may emit red light, and the third main sub-pixel Pmb may emit blue light. The main sub-pixels Pm may be arranged in a Pentile Matrix structure.

For example, the first main sub-pixels Pmg may be arranged apart from one another in a first main line ML1 that is a virtual straight line extending in the first direction (e.g., the x direction). The second main sub-pixels Pmr and the third main sub-pixels Pmb may be alternately arranged in a second main line ML2 that is a virtual line being apart from the first main line ML1 in the second direction (e.g., the y direction) and extending in the first direction (e.g., the x direction). The first main sub-pixels Pmg arranged in the first main line ML1 and the second main sub-pixels Pmr and the third main sub-pixels Pmb arranged in the second main line ML2 may be arranged in a zig-zag manner. The first main sub-pixels Pmg may be arranged apart from one another in a third main line ML3 that is a virtual line being apart from the second main line ML2 by a certain distance in the second direction (e.g., the y direction) and extending in the first direction (e.g., the x direction). The third main sub-pixels Pmb and the second main sub-pixels Pmr may be alternately arranged in a fourth main line ML4 that is a virtual line being apart from the third main line ML3 by a certain distance in the second direction (e.g., the y direction) and extending in the first direction (e.g., the x direction). The first main sub-pixels Pmg arranged in the third main line ML3 and the third main sub-pixels Pmb and the second main sub-pixels Pmr arranged in the fourth main line ML4 may be arranged in a zig-zag manner.

In other words, from among vertices of a virtual square having a center point of the first main sub-pixel Pmg as a center point of the square, the second main sub-pixels Pmr may be arranged at first and third vertices facing each other, and the third main sub-pixels Pmb may be arranged at second and fourth vertices. According to some embodiments, a size (that is, an emission area) of the first main sub-pixel Pmg may be smaller than sizes (that is, emission areas) of the second main sub-pixel Pmr and the third main sub-pixel Pmb.

This type of pixel arrangement structure is referred to as a Pentile Matrix structure or a Pentile structure, and by adopting rendering driving, in which colors are expressed by sharing neighboring pixels, a high resolution may be implemented by using a small number of pixels.

Although FIGS. 11A, 11B, and 12 illustrate that the plurality of main sub-pixels Pm are arranged in a Pentile Matrix structure, the embodiments are not limited thereto. For example, the plurality of main sub-pixels Pm may be arranged in various forms, such as a stripe structure, a mosaic arrangement structure, a delta arrangement structure, and the like.

Although FIGS. 11A, 11B, and 12 illustrate that the plurality of main sub-pixels Pm have circular shapes on a plane, the embodiments are not limited thereto. The plurality of main sub-pixels Pm may have various shapes such as a circle, an oval, a polygon, and the like.

The plurality of auxiliary sub-pixels Pa may be arranged in the second display area DA2.

According to some embodiments, the plurality of auxiliary sub-pixels Pa arranged in the second display area DA2 may include a plurality of first auxiliary sub-pixels Pag, a plurality of second auxiliary sub-pixels Par, and a plurality of third auxiliary sub-pixels Pab. The first auxiliary sub-pixels Pag may emit green light, the second auxiliary sub-pixels Par may emit red light, and the third auxiliary sub-pixels Pab may emit blue light.

According to some embodiments, the first auxiliary sub-pixels Pag may be arranged apart from one another in a first auxiliary line A1 that is a virtual straight line extending in the first direction (e.g., the x direction). The second auxiliary sub-pixels Par and the third auxiliary sub-pixels Pab may be alternately arranged in a second auxiliary line AL2 that is a virtual line being apart from the first auxiliary line A1 by a certain distance in the second direction (e.g., the y direction) and extending in the first direction (e.g., the x direction). A third auxiliary line AL that is a virtual straight line extending in the second direction (e.g., the y direction) may pass a center of the first auxiliary sub-pixel Pag in the first auxiliary line A1 and a center of the second auxiliary sub-pixel Par in the second auxiliary line AL2. A fourth auxiliary line AL4, which is a virtual line being apart from the third auxiliary line AL3 by a certain distance in the first direction (e.g., the x direction) and extending in the second direction (e.g., the y direction), may pass the center of the first auxiliary sub-pixel Pag in the first auxiliary line A1 and a center of the third auxiliary sub-pixel Pab in the second auxiliary line AL2. Here, the second direction (e.g., the y direction) may include a direction crossing the first direction (e.g., the x direction), that is, a direction orthogonal to the first direction (e.g., the first direction).

The first auxiliary lines A1 and the second auxiliary lines AL2 may be repeatedly arranged apart from each other in the second direction (e.g., the y direction). Likewise, the third auxiliary line AL3 and the fourth auxiliary line AL4 may be repeatedly arranged apart from each other in the first direction (e.g., the x direction).

In other words, in a virtual rectangle having center points of two neighboring first auxiliary sub-pixels Pag as first and second vertices, a center point of the second auxiliary sub-pixel Par and a center point of the third auxiliary sub-pixel Pab may be arranged at remaining vertices, that is, third and fourth vertices.

As a center of the first auxiliary sub-pixel Pag and a center of the second auxiliary sub-pixel Par and the center of the first auxiliary sub-pixel Pag and the third auxiliary sub-pixel Pab are in a straight line extending in the second direction (e.g., the y direction), visibility of a boundary between the first display area DA1 and the second display area DA2 may be reduced. As a Comparative Example, when the auxiliary sub-pixels arranged in the second display area DA have a PenTile Matrix structure identical to the structure of the first display area DA1, boundary pairs extending in the second direction (e.g., the y direction) and facing each other may have different distances from the boundary to the first auxiliary sub-pixels Pag. Accordingly, a difference in luminance of the boundaries extending in the second direction (e.g., the y direction) may be visually recognized. On the other hand, in the embodiments, at the boundary between the first display area DA1 and the second display area DA2, at which the first display area DA1 and the second display area DA2 contact each other, extending in the second direction (e.g., the y direction), the first auxiliary sub-pixels Pag may be arranged at a same distance from the boundary.

According to some embodiments, in the boundaries at which the first display area DA1 and the second display area DA2 contact each other, the second boundary BP2 may extend in the first direction (e.g., the x direction). In the second display area DA2, the second auxiliary sub-pixels Par and the third auxiliary sub-pixels Pab may be alternately arranged in a second′ auxiliary line AL2′ that is most adjacent to the second boundary BP2. In the first display area DA1, the first main sub-pixels Pmg may be arranged in the first main line ML1 that is most adjacent to the second boundary BP2. The second boundary BP2 may be between the second′ auxiliary line AL2′ and the first main line ML1 being apart in the second direction (e.g., the y direction) and neighboring each other. In other words, the second auxiliary sub-pixel Par and the third auxiliary sub-pixel Pab, and the first main sub-pixel Pmg, may be arranged apart in the second direction (e.g., the y direction), with the second boundary BP2 therebetween.

The second display area DA2 may include a boundary area BA adjacent to the second boundary BP2. For example, as shown in FIG. 11A, the boundary area BA may include sub-pixel columns most adjacent to the second boundary BP2. The boundary area BA may include the second′ auxiliary line AL2′ most adjacent to the second boundary BP2 and a first′ auxiliary line AL1′ neighboring the second′ auxiliary line AL2′. According to some embodiments, as shown in FIG. 12, the boundary area BA may include a plurality of sub-pixel columns adjacent to the second boundary BP2. The boundary area BA may include one second′ auxiliary line AL2′ most adjacent to the second boundary BP2, the first′ auxiliary line AL1′ neighboring the second′ auxiliary line AL2′, a second″ auxiliary line AL2″, and a first″ auxiliary line AL1″.

A sub sub-pixel Ps may be arranged in the second auxiliary sub-pixel Par and the third auxiliary sub-pixel Pab being arranged in the boundary area BA and neighboring each other in the first direction (e.g. the x direction). According to some embodiments, as shown in FIGS. 11A and 11B, the second auxiliary sub-pixel Par, the sub sub-pixel Ps, and the third auxiliary sub-pixel Pab may be alternately arranged in the second′ auxiliary line AL2′ most adjacent to the second boundary BP2. According to some embodiments, as shown in FIG. 12, the second auxiliary sub-pixel Par, the sub sub-pixel Ps, and the third auxiliary sub-pixel Pab may be alternately arranged in one second′ auxiliary line AL2′ most adjacent to the second boundary BP2, and the third auxiliary sub-pixel Pab, the sub sub-pixel Ps, and the second auxiliary sub-pixel Par may be alternately arranged in the second″ auxiliary line AL2″ adjacent to the second′ auxiliary line AL2′.

The sub sub-pixel Ps may include a display element emitting green light. According to some embodiments, a size (that is, an emission area) of the sub sub-pixel Ps may be identical to the size (that is, the emission area) of the first main sub-pixel Pmg. According to some embodiments, the size (that is, the emission area) of the sub sub-pixel Ps may be greater than the size (i.e. the emission area) of the first main sub-pixel Pmg and smaller than a size (i.e., an emission area) of the first auxiliary sub-pixel Pag.

According to some embodiments, the sub sub-pixel Ps and the first auxiliary sub-pixel Pag adjacent thereto may emit light in response to a same signal. The sub sub-pixel Ps and the first auxiliary sub-pixel Pag may simultaneously emit light. In other words, the sub sub-pixel Ps and the first auxiliary sub-pixel Pag adjacent thereto may be connected to a same auxiliary pixel circuit PCa. For example, as shown in FIGS. 11A and 12, a pixel electrode of the sub sub-pixel Ps may be electrically connected to a pixel electrode of the first auxiliary sub-pixel Pag adjacent to the sub sub-pixel Ps by a pixel connection wiring PCW.

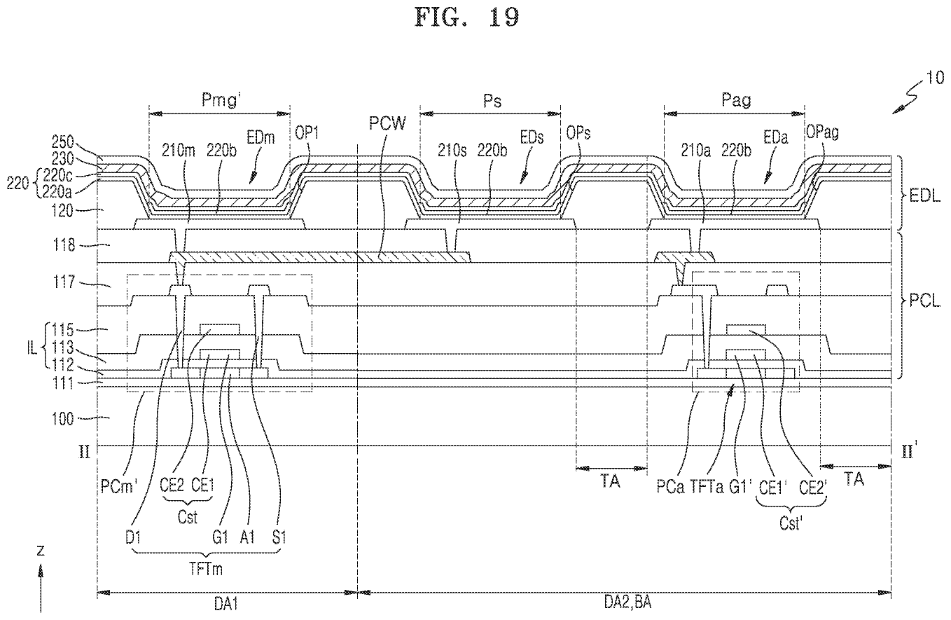

According to some embodiments, the sub sub-pixel Ps may emit light in response to the signal applied to the first main sub-pixel Pmg′ (see FIG. 11b) adjacent to the sub sub-pixel Ps. The sub sub-pixel Ps and the first main sub-pixel Pmg′ adjacent thereto may be connected to a same main pixel circuit Pcm′ (see FIG. 19). For example, as shown in FIG. 11B, a pixel electrode of the sub sub-pixel Ps may be electrically connected to a pixel electrode of the first main sub-pixel Pmg′ adjacent to the sub sub-pixel Ps by the pixel connection wiring PCW (see FIG. 19).

In this case, a driving thin-film transistor and a storage capacitor, which form the main pixel circuit Pcm′ (see FIG. 19) of the first main sub-pixel Pmg′ connected to the sub sub-pixel Ps in the first display area DA1, may be different from a driving thin-film transistor and a storage capacitor forming a main pixel circuit of the first main sub-pixel Pmg that is not connected to the sub sub-pixel Ps in the first display area DA1. In other words, the main pixel circuit PCm′ of the first main sub-pixel Pmg′ connected to the sub sub-pixel Ps may be different from the main pixel circuit of the first main sub-pixel Pmg that is not connected to the sub sub-pixel Ps.

According to some embodiments, some of the sub sub-pixel Ps emits light in response to a same signal as the signal applied to the first auxiliary sub-pixel Pag adjacent to the sub sub-pixel Ps, and others of the sub sub-pixel Ps may emit light in response to a same signal as the signal applied to the first main sub-pixel Pmg′ adjacent to the sub sub-pixel Ps.

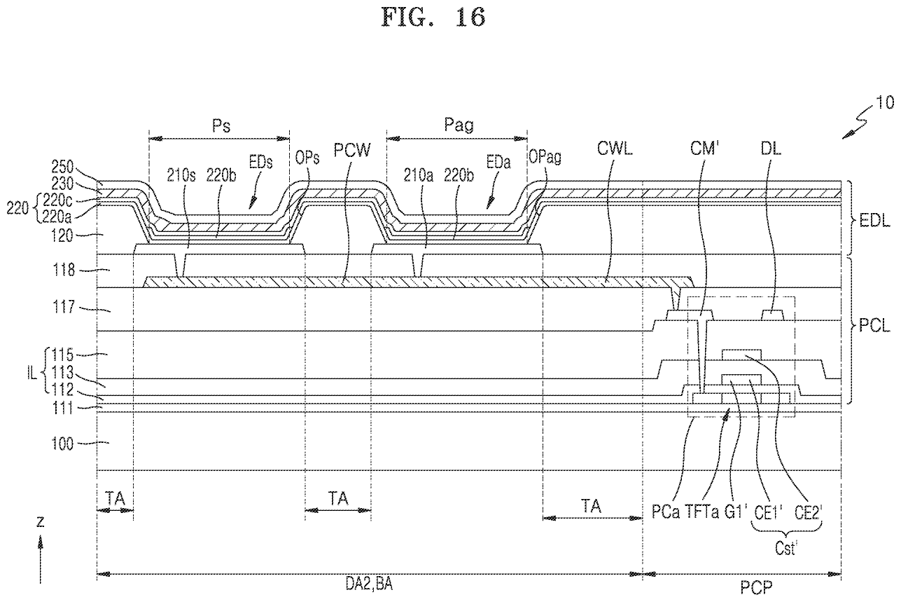

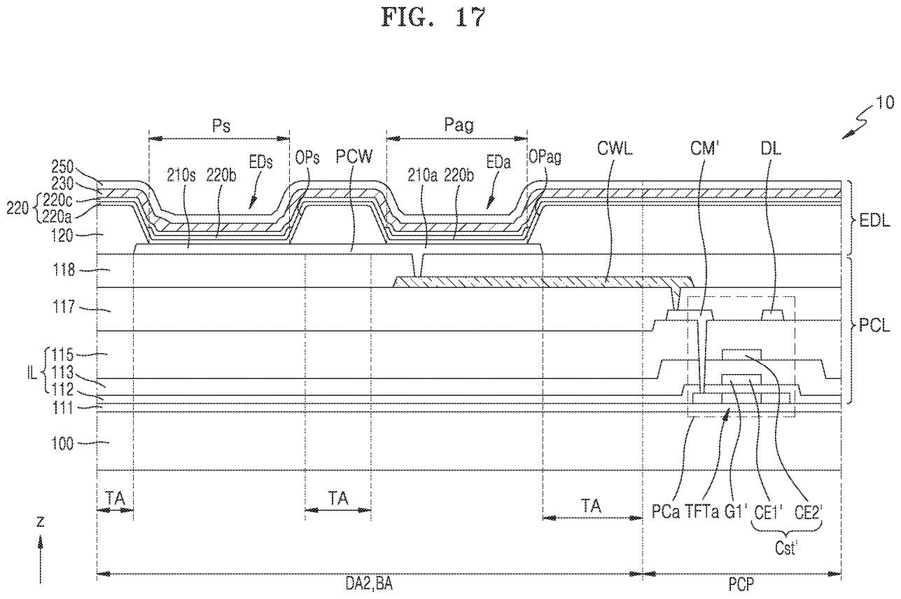

The pixel connection wiring PCW may be on a same layer as the connection wiring CWL connecting an auxiliary pixel circuit PCa (see FIG. 16) and an auxiliary display element EDa (see FIG. 16) with each other. Alternatively, the pixel connection wiring PWC may be on a same layer as a pixel electrode 210a of the auxiliary display element EDa (see FIG. 17) and a pixel electrode 210s of a sub display element EDs (see FIG. 17).

Although FIGS. 11A, 11B, and 12 illustrate that the plurality of auxiliary sub-pixels Pa and sub sub-pixels Ps have a circular shape on a plane, the embodiments, are not limited thereto. Each of the plurality of auxiliary sub-pixels Pa and sub sub-pixels Ps may have various shapes such as a circle, an oval, a polygon, and the like.

At a boundary (e.g., the second boundary BP2) at which the first display area DA1 and the second display area DA2 contact each other, extending in the first direction (e.g., the x direction), when the second auxiliary sub-pixel Par, the third auxiliary sub-pixel Pab, and the first main sub-pixel Pmg are adjacent to one another, the boundary may be visually recognized due to difference in the number per unit area of the sub-pixels emitting green light. Therefore, in some embodiments, the visibility of the boundary may be prevented or reduced by arranging the sub sub-pixels Ps in the boundary area BA.

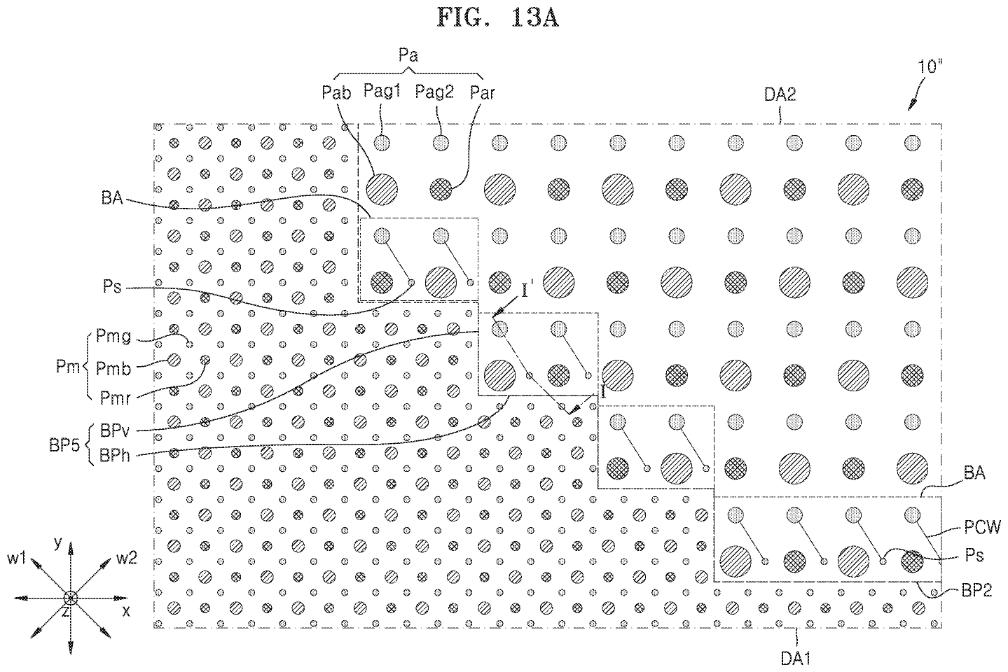

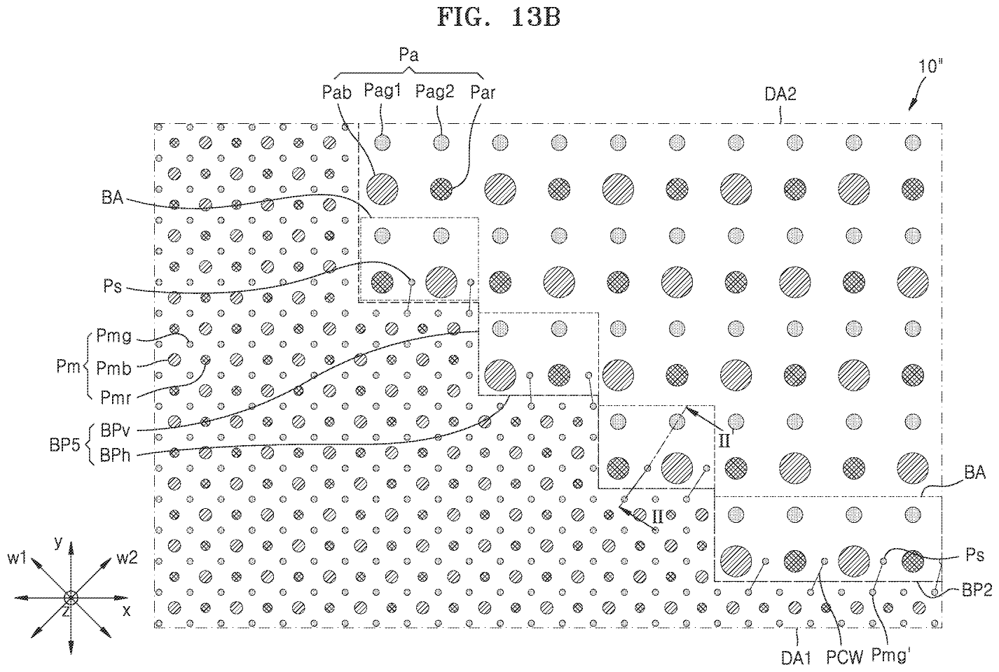

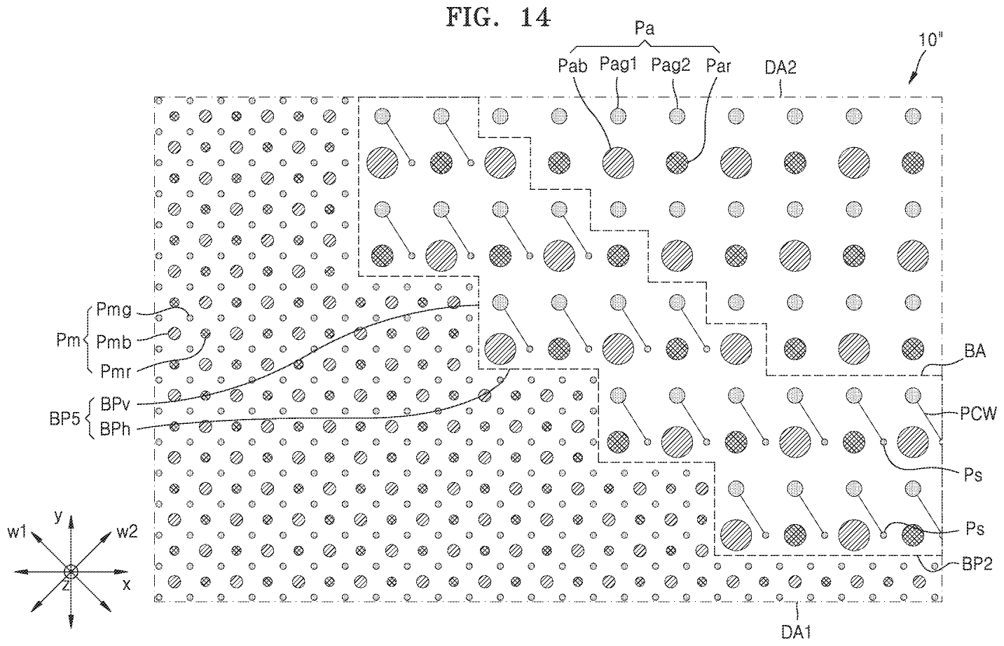

FIGS. 13A, 13B, and 14 are top plan views each schematically illustrating an arrangement of pixels of the display panel according to some embodiments. FIGS. 13A, 13B, and 14 are enlarged views of a portion of the display panel shown in FIG. 8 and illustrate a portion of each of the first display area DA1 and the second display area DA2 adjacent to the second boundary BP2 and a fifth boundary BP5.

Referring to FIGS. 13A, 13B, and 14, the plurality of main sub-pixels Pm may be arranged in the first display area DA1. The main sub-pixels Pm may be arranged in a Pentile Matrix structure. However, the embodiments are not limited thereto. For example, the plurality of main sub-pixels Pm may be arranged in various forms, such as a stripe structure, a mosaic arrangement structure, a delta arrangement structure, and the like.

The plurality of auxiliary sub-pixels Pa may be arranged in the second display area DA2.

According to some embodiments, the plurality of auxiliary sub-pixels Pa arranged in the second display area DA2 may include the plurality of first auxiliary sub-pixels Pag, the plurality of second auxiliary sub-pixels Par, and the plurality of third auxiliary sub-pixels Pab. The first auxiliary sub-pixel Pag may emit green light, the second auxiliary sub-pixel Par may emit red light, and the third auxiliary sub-pixel Pab may emit blue light.

In the virtual rectangle having the center points of two neighboring first auxiliary sub-pixels Pag as first and second vertices, the center point of the second auxiliary sub-pixel Par and the center point of the third auxiliary sub-pixel Pab may be arranged at the remaining vertices, that is, the third and fourth vertices.

In the boundaries at which the first display area DA1 and the second display area DA2 contact each other, the second boundary BP2 may extend in the first direction (e.g. the x direction). The first main sub-pixels Pmg may be arranged apart from the second auxiliary sub-pixels Par and the third auxiliary sub-pixels Pab in the second direction (e.g., the y direction), with the second boundary BP2 therebetween.

As described with reference to FIG. 8, the fifth boundary BP5 extends in a first diagonal direction (e.g., w1), and when enlarged in pixel units, the fifth boundary BP5 may include a plurality of horizontal boundaries BPh extending in the first direction (e.g., the x direction) and a plurality of vertical boundaries BPv extending in the second direction (e.g., the y direction). By connection between the plurality of horizontal boundaries BPh and the plurality of vertical boundaries BPv, the fifth boundary BP5 generally extending in the first diagonal direction (e.g., w1) may be implemented.

The first main sub-pixels Pmg may be arranged apart from the first auxiliary sub-pixel Pag, the second auxiliary sub-pixel Par, and the third auxiliary sub-pixel Pab in the first direction (e.g., the x direction) with the vertical boundary BPv therebetween. The first main sub-pixels Pmg may be arranged apart from the second auxiliary sub-pixels Par and the third auxiliary sub-pixels Pab in the second direction (e.g., the y direction), with the horizontal boundary BPh therebetween.

According to some embodiments, the second display area DA2 may include boundary areas BA adjacent to the horizontal boundaries BPh of the second boundary BP2 and the fifth boundary BP5. For example, as shown in FIGS. 13A and 13B, the boundary area BA may include one sub-pixel column, which is most adjacent to the horizontal boundaries BPh of the second boundary BP2 and the fifth boundary BP5, and a sub-pixel column neighboring the one sub-pixel column. According to some embodiments, as shown in FIG. 14, the boundary area BA may include a plurality of sub-pixel columns adjacent to the horizontal boundaries BPh of the second boundary BP2 and the fifth boundary BP5. Accordingly, the boundary areas BA adjacent to the horizontal boundaries BPh of the second boundary BP2 and the fifth boundary BP5 may be connected into an area.

A sub sub-pixel Ps may be arranged in the second auxiliary sub-pixel Par and the third auxiliary sub-pixel Pab being arranged in the boundary area BA and neighboring each other in the first direction (e.g. the x direction).

According to some embodiments, the sub sub-pixel Ps and the first auxiliary sub-pixel Pag adjacent thereto may emit light in response to a same signal. The sub sub-pixel Ps and the first auxiliary sub-pixel Pag may simultaneously emit light. In other words, the sub sub-pixel Ps and the first auxiliary sub-pixel Pag adjacent thereto may be connected to a same auxiliary pixel circuit PCa. For example, as shown in FIGS. 13A and 14, the pixel electrode of the sub sub sub-pixel Ps may be electrically connected to the pixel electrode of the first auxiliary sub-pixel Pag adjacent to the sub sub-pixel Ps by the pixel connection wiring PCW.

According to some embodiments, the sub sub-pixel Ps and the first main sub-pixel Pmg′ (see FIG. 13b) adjacent thereto may emit light in response to a same signal. The sub sub-pixel Ps and the first main sub-pixel Pmg′ adjacent thereto may be connected to a same main pixel circuit PCm′ (see FIG. 19). For example, as shown in FIG. 13B, the pixel electrode of the sub sub-pixel Ps may be electrically connected to the pixel electrode of the first main sub-pixel Pmg′ adjacent to the sub sub-pixel Ps by the pixel connection wiring PCW (see FIG. 19).

In this case, a driving thin-film transistor and a storage capacitor, which form the main pixel circuit Pcm′ (see FIG. 19) of the first main sub-pixel Pmg′ connected to the sub sub-pixel Ps in the first display area DA1, may be different from a driving thin-film transistor and a storage capacitor forming a main pixel circuit of the first main sub-pixel Pmg that is not connected to the sub sub-pixel Ps in the first display area DA1.

According to some embodiments, a portion of the sub sub-pixel Ps emits light in response to a same signal as the signal applied to the first auxiliary sub-pixel Pag adjacent to the sub sub-pixel Ps, and another portion of the sub sub-pixel Ps may emit light in response to a same signal as the signal applied to the first main sub-pixel Pmg′ adjacent to the sub sub-pixel Ps.

Although FIGS. 13A, 13B, and 14 mainly illustrate the second boundary BP2 and the fifth boundary BP5 of the second display area DA2 that is approximately octagonal, the boundary area BA and the sub sub-pixels Ps may be arranged in the second display area DA2 adjacent to the sixth boundary BP6 (see FIG. 8) extending in a second diagonal direction (e.g., w2 direction).

In other embodiments, the second display area DA2 may have a circle shape, an oval shape, a polygon shape, or an amorphous shape. As described above, a boundary of the second display area DA2 having various shapes may include a combination of the vertical boundary BPv and the horizontal boundary BPh. As the first main sub-pixels Pmg are adjacent to the horizontal boundaries BPh adjacently apart from the second auxiliary sub-pixel Par and the third auxiliary sub-pixel Pab in the second direction (e.g., the y direction), the boundary area BA may be arranged in the second display area DA2. As the sub sub-pixel Ps is arranged between the second auxiliary sub-pixel Par and the third auxiliary sub-pixel Pab in the boundary area BA, visibility of the boundary due to a difference in the number per unit area of the sub-pixels emitting green light, in the first display area DA1 and the second display area DA2, may be prevented or reduced.

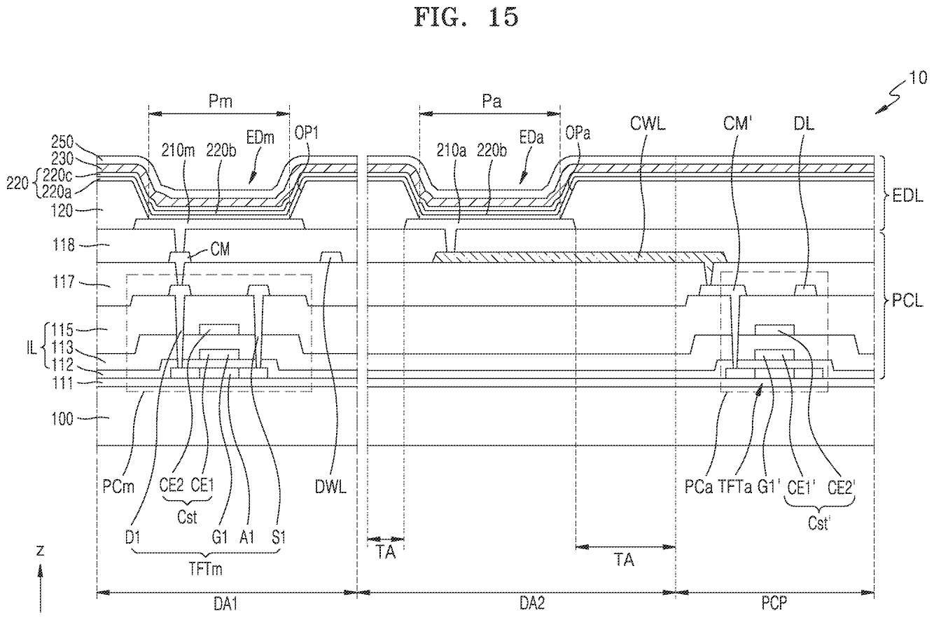

FIG. 15 is a cross-sectional view schematically illustrating a portion of the display panel according to an embodiment; FIG. 15 schematically illustrates a portion of each of the first display area DA1, the second display area DA2, and the pixel circuit part PCP.

Referring to FIG. 15, the main sub-pixel Pm is arranged in the first display area DA1, and the second display area DA2 includes the auxiliary sub-pixel Pa and the transmission area TA. The main pixel circuit PCm, which includes the main thin-film transistor TFTm and a main storage capacitor Cst, and the main display element EDm, which is a display element connected to the main pixel circuit PCm, may be arranged in the first display area DA1. The auxiliary display element EDa may be arranged in the second display area DA2. The auxiliary pixel circuit PCa, which includes the auxiliary thin-film transistor TFTa and an auxiliary storage capacitor Cst′, may be arranged in the pixel circuit part PCP. Although FIG. 15 illustrates that the pixel circuit part PCP is outside the second display area DA2, according to some embodiments, as described with reference to FIG. 4, the second display area DA2 may include the component area CA and the pixel circuit part PCP arranged outside the component area CA. The connection wiring CWL connecting the auxiliary pixel circuit PCa and the auxiliary display element EDa with each other may be arranged in the second display area DA2 and the pixel circuit part PCP.

Hereinafter, a stack structure including components of the display panel 10 will be described. The substrate 100, a buffer layer 111, a circuit layer PCL, a display element layer EDL may be stacked in the display panel 10.

The substrate 100 may include an insulating material such as glass, quartz, and a polymer resin. The substrate 100 may include a rigid substrate or a flexible substrate that may be bent, folded, or rolled.

The buffer layer 111, which is located on the substrate 100, may reduce or prevent permeation of foreign materials, moisture, or external air from beneath the substrate 100, and may provide a plane surface on the substrate 100. The buffer layer 111 may include an inorganic material such as an oxide or a nitride, an organic material, or an organic-inorganic compound, and may include a single-layer or multi-layer structure including inorganic materials and organic materials. A barrier layer preventing permeation of external air may be further provided between the substrate 100 and the buffer layer 111. According to some embodiments, the buffer layer 111 may include silicon oxide (SiOₓ), silicon nitride (SiNₓ), or silicon oxynitride (SiON).

The circuit layer PCL may be located on the buffer layer 111, and may include the pixel circuits (i.e., the main pixel circuit PCm and the auxiliary pixel circuit PCa), a first gate insulating layer 112, a second gate insulating layer 113, an interlayer insulating layer 115, a first planarization layer 117, and a second planarization layer 118. The main pixel circuit PCm may include the main thin-film transistor TFTm and the main storage capacitor Cst; and the auxiliary pixel circuit PCa may include an auxiliary thin-film transistor TFTa and an auxiliary storage capacitor Cst′.

The main thin-film transistor TFTm and the auxiliary thin-film transistor TFTa may be located on the buffer layer 111. The main thin-film transistor TFTm includes a semiconductor layer A1, a gate electrode G1, a source electrode S1, and a drain electrode D1. The main thin-film transistor TFTm may be connected to the main display element EDm and drive the main display element EDm. The auxiliary thin-film transistor TFTa may be connected to the auxiliary display element EDa and drive the auxiliary display element EDa. As the auxiliary thin-film transistor TFTa has a configuration similar to a configuration of the main thin-film transistor TFTm, description of the auxiliary thin-film transistor TFTa will be replaced with description of the main thin-film transistor TFTm.

The semiconductor layer A1 may be located on the buffer layer 111 and may include polysilicon. According to some embodiments, the semiconductor layer A1 may include amorphous silicon. According to some embodiments, the semiconductor layer A1 may include an oxide of at least one material selected from among a group including indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer A1 may include a channel area, a source area doped with impurities, and a drain area.

The first gate insulating layer 112 may cover the semiconductor layer A1. The first gate insulating layer 112 may include an inorganic insulating material such as SiOₓ, SiNₓ, SiON, aluminum oxide (Al₂O₃), titanium oxide (TiO₂), tantalum oxide (Ta₂O₅), hafnium oxide (HfO₂), zinc oxide (ZnO₂), or the like. The first gate insulating layer 112 may include a single layer or a multi-layer including the aforementioned inorganic insulating materials.

The gate electrode G1 is located on the first gate insulating layer 112 to overlap the semiconductor layer A1. The gate electrode G1 may include molybdenum (mo), aluminum (Al), copper (Cu), titanium (Ti), and the like, and may include a single layer or multiple layers. For example, the gate electrode G1 may include a single layer including Mo.

The second gate insulating layer 113 may cover the gate electrode G1. The second gate insulating layer 113 may include an inorganic insulating material such as SiOₓ, SiN_{X}, SiON, Al₂O₃, TiO₂, Ta₂O₅, HfO₂, ZnO₂, or the like. The second gate insulating layer 113 may include a single layer or a multi-layer including the aforementioned inorganic insulating materials.

An upper electrode CE2 of the main storage capacitor Cst and an upper electrode CE2′ of the auxiliary storage capacitor Cst′ may be located on the second gate insulating layer 113.

In the first display area DA1, the upper electrode CE2 of the main storage capacitor Cst may overlap with the gate electrode G1 thereunder. The gate electrode G1 and the upper electrode CE2, which overlap with each other with the second gate insulating layer 113 therebetween, may be included in the main storage capacitor Cst. The gate electrode G1 may function as a lower electrode CE1 of the main storage capacitor Cst.

In the peripheral area DPA, the upper electrode CE2′ of the auxiliary storage capacitor Cst′ may overlap with a gate electrode G1′ of the auxiliary thin-film transistor TFTa under the auxiliary storage capacitor Cst′. The gate electrode G1′ of the auxiliary thin-film transistor TFTa may include a lower electrode CE1′ of the auxiliary thin-film transistor TFTa.

The upper electrodes (i.e., the upper electrode CE2 of the main storage capacitor Cst and the upper electrode CE2′ of the auxiliary storage capacitor Cst′) may include Al, platinum (Pt), palladium (Pd), silver (Ag), magnesium (Mg), gold (Au), nickel (Ni), neodymium (Nd), iridium (Ir), Cr, Ca, Mo, Ti, tungsten (W), and/or copper (Cu), and may include a single layer or a multi-layer including the aforementioned materials.

The interlayer insulating layer 115 may cover the upper electrodes (i.e., the upper electrode CE2 of the main storage capacitor Cst and the upper electrode CE2′ of the auxiliary storage capacitor Cst′). The interlayer insulating layer 115 may include SiOₓ, SiN_{X}, SiON, Al₂O₃, TiO₂, Ta₂O₅, HfO₂, ZnO₂, or the like. The interlayer insulating layer 115 may include a single layer or a multiple-layer including the aforementioned inorganic insulating materials.

The source electrode S1 and the drain electrode D1 may be located on the interlayer insulating layer 115. The source electrode S1 and the drain electrode D1 may include conductive materials including Mo, Al, Cu, Ti, and the like, and may include a multi-layer or a single layer including the aforementioned materials. For example, the source electrode S1 and the drain electrode D1 may include a multiple-layer structure including Ti/AI/Ti. In addition, the data line DL may be located on the interlayer insulating layer 115.

The first planarization layer 117 and the second planarization layer 118 may cover the source electrode S1 and the drain electrode D1. The first planarization layer 117 and/or the second planarization layer 118 may have flat top surfaces such that a main pixel electrode 210 and an auxiliary pixel electrode 210′ located thereon may be formed in a flat shape.

The first planarization layer 117 and the second planarization layer 118 may include organic or inorganic materials, and may have a single-layer structure of a multi-layer structure. Accordingly, a conducting pattern such as wirings may be formed between the first planarization layer 117 and the second planarization layer 118, and thus may be profitable for high integration. The first planarization layer 117 may cover the pixel circuits (i.e., the main pixel circuit PCm and the auxiliary pixel circuit PCa). The second planarization layer 118 may be located on the first planarization layer 117 and may have a flat top surface such that the pixel electrodes (i.e., the main pixel electrode 210 and the auxiliary pixel electrode 210′) may be formed flat.

Each of the first planarization layer 117 and the second planarization layer 118 may include a general-purpose polymer such as Benzocyclobutene (BCB), polyimide, hexamethyldisiloxane (HMDSO), polymethylmethacrylate (PMMA), or polystyrene (PS), a polymer derivative having a phenolic group, an acryl-based polymer, an imide-based polymer, an arylether-based polymer, an amide-based polymer, a fluoropolymer, a p-xylene based polymer, or a vinylalcohol-based polymer. Each of the first planarization layer 117 and the second planarization layer 118 may include an inorganic insulating material such as SiOₓ, SiNₓ, SiON, Al₂O₃, TiO₂, Ta₂O₅, HfO₂, ZnO₂, or the like. When the first planarization layer 117 is formed, after a layer is formed, chemical and/or mechanical polishing may be performed on a top surface of the layer to provide a flat top surface.

A connection electrode CM, an auxiliary connection electrode CM′, a connection wiring CWL and a data connection line DWL may be located on the first planarization layer 117.

The connection wiring CWL may be located on the first planarization layer 117. An end of the connection wiring CWL may be electrically connected to the auxiliary thin-film transistor TFTa through the auxiliary connection electrode CM′. Another end of the connection wiring CWL may be electrically connected to the pixel electrode 210a of the auxiliary display element EDa. The connection wiring CWL may connect the auxiliary thin-film transistor TFTa and the auxiliary display element EDa in the second display area DA2 to each other. The connection wiring CWL may pass the transmission area TA of the second display area DA2.

The connection wiring CWL may include conductive materials including Mo, Al, Cu, Ti, and the like, and may include a multi-layer or a single layer including the aforementioned materials. Alternatively, the connection wiring CWL may include a transparent conducting material. For example, the connection wiring CWL may include a transparent conducting oxide (TCO). The connection wiring CWL may include a conducting oxide such as indium tin oxide (ITO), indium zinc oxide (IZO), zinc oxide (ZnO), indium oxide (In₂O₃), indium gallium oxide (IGO), or aluminum zinc oxide (AZO).

The main display element EDm and the auxiliary display element EDa are located on the second planarization layer 118. The pixel electrode 210m of the main display element EDm may be connected to the main pixel circuit PCm through the connection electrode CM located on the first planarization layer 117. The pixel electrode 210a of the auxiliary display element EDa may be connected to the auxiliary pixel circuit PCa through the connection wiring CWL located on the first planarization layer 117.

The pixel electrode 210m of the main display element EDm and the pixel electrode 210a of the auxiliary display element EDa may include a conducting oxide such as ITO, IZO, ZnO, In₂O₃, IGO, or AZO. The pixel electrode 210m of the main display element EDm and the pixel electrode 210a of the auxiliary display element EDa may each include a reflective film including Ag, Mg, Al, Pt, Pd, Au, Ni, Nd, Ir, Cr, or combinations thereof. For example, the pixel electrode 210m of the main display element EDm and the pixel electrode 210a of the auxiliary display element EDa may have a structure in which films including ITO, IZO, ZnO, or In₂O₃ are formed under/above the reflective film described above. The pixel electrode 210m of the main display element EDm and the pixel electrode 210a of the auxiliary display element EDa may each have a stack structure including ITO/Ag/ITO.

A pixel defining film 120 is located on the second planarization layer 118 to cover edges of each of the pixel electrode 210m of the main display element EDm and the pixel electrode 210a of the auxiliary display element EDa. The pixel defining film 120 may include a first opening OP1 exposing a center portion of the pixel electrode 210m of the main display element EDm and a second opening OP2 exposing a center portion of the pixel electrode 210a of the auxiliary display element EDa. Emission areas of the main display element EDm and the auxiliary display element EDa, that is, sizes and shapes of the main sub-pixel Pm and the auxiliary sub-pixel Pa, are defined by the first opening OP1 and the second opening OP2.

The pixel defining film 120 may increase a distance from the edges of the pixel electrode 210m of the main display element EDm and the pixel electrode 210a of the auxiliary display element EDa to the counter electrode 230, to thereby prevent arcs and the like generated at the edges of the pixel electrode 210m of the main display element EDm and the pixel electrode 210a of the auxiliary display element EDa. The pixel defining film 120 may be formed by a method such as spin coating by using an organic insulating material such as polyimide, polyamide, an acryl resin, BCB, HMDSO, a phenolic resin, and the like.

In the first opening OP1 and the second opening OP2 of the pixel defining film 120, emission layers 220b corresponding to the pixel electrode 210m of the main display element EDm and the pixel electrode 210a of the auxiliary display element EDa are arranged. The emission layer 220b may include a high-molecular weight material or a low-molecular weight material, and may emit red, green, blue, or white light.

An organic function layer 220 may be located on/under the emission layer 220b. The organic function layer 220 may include a first function layer 220a and a second function layer 220c. The first function layer 220a or the second function layer 220c may be omitted.

The first function layer 220a may be located under the emission layer 220b. The first function layer 220a may include a single layer or a multi-layer including organic materials. The first function layer 220a may include a hole transport layer (HTL) having a single-layer structure. In addition, the first function layer 220a may also include a hole injection layer (HIL) and a hole transport layer (HTL). The first function layer 220a may be integrally formed with the main display element EDm included in the first display area DA1 and the auxiliary display element EDa included in the second display area DA2 in an overlapping manner.

The second function layer 220c may be located on the emission layer 220b. The second function layer 220c may include a single layer or a multiple-layer including organic materials. The second function layer 220c may include an electron transport layer (ETL) or an electron injection layer (EIL). The second function layer 220c may be integrally formed with the main display element EDm included in the first display area DA1 and the auxiliary display element EDa included in the second function layer 220c in an overlapping manner.

The counter electrode 230 is located on the second function layer 220c. The counter electrode 230 may include a conducting material having a small work function. For example, the counter electrode 230 may include a (semi)transparent layer including Ag, Mg, Al, Pt, Pd, Au, Ni, Nd, Ir, Cr, Li, Ca, or alloys thereof. Alternatively, the counter electrode 230 may further include a layer including a material such as ITO, IZO, ZnO, or In₂O₃, on the (semi) transparent layer including the aforementioned materials. The counter electrode 230 may be integrally formed with the main display element EDm included in the first display area DA1 and the auxiliary display element EDa included in the second display area DA2 in a corresponding manner.

An upper layer 250 including an organic material may be formed on the counter electrode 230. The upper layer 250 may be provided to protect the counter electrode 230 and increase light-extraction efficiency of the main display element EDm and the auxiliary display element EDa. The upper layer 250 may include organic materials having a refractive index greater than a refractive index of the counter electrode 230. Alternatively, the upper layer 250 may include stacked layers respectively having different refractive indices. For example, the upper layer 250 may include high-refractive index layer/low-refractive index layer/high-refractive index layer stacked together. Here, a refractive index of the high-refractive index layer may be 1.7 or greater, and a refractive index of the low-refractive index layer may be 1.3 or less.

The upper layer 250 may further include LiF. Alternatively, the upper layer 250 may further include inorganic insulating materials such as SiOₓ and SiNₓ.

FIGS. 16 and 17 are cross-sectional views each schematically illustrating a portion of the display panel according to some embodiments. FIGS. 16 and 17 schematically illustrate: the sub sub-pixel Ps in the boundary area BA of the second display area DA2; the first auxiliary sub-pixel Pag adjacent to the sub sub-pixel Ps and emitting light in response to a same signal as a signal transmitted to the sub sub-pixel Ps; and the auxiliary pixel circuit PCa in the pixel circuit part PCP. Here, the first auxiliary sub-pixel Pag emitting light in response to the same signal as the signal transmitted to the sub sub-pixel Ps may include any one of the first auxiliary sub-pixels Pags most adjacent to the sub sub-pixel Ps.

Referring to FIG. 16, the auxiliary display element EDa and a sub display element EDs are located on the second planarization layer 118 of the boundary area BA. In the second display area DA2 in which the auxiliary display element EDa is located, the boundary area BA may include an area adjacent to a boundary of the second display area DA2 in the first direction (e.g., the x direction). A sub-pixel column including the sub sub-pixel Ps and a neighboring column of the first auxiliary sub-pixel Pag may be in the boundary area BA. The emission layer 220b of the auxiliary display element EDa and the emission layer 220b of the sub display element EDs may emit green light. The pixel defining film 120 covers edges of each of the pixel electrode 210a of the auxiliary display element EDa and a pixel electrode 210s of the sub display element EDs. The pixel defining film 120 may include an auxiliary opening OPag exposing the center portion of the pixel electrode 210a of the auxiliary display element EDa and a sub opening OPs exposing a center of the pixel electrode 210s of the sub display element EDs. Emission areas of the auxiliary display element EDa and the sub display element EDs, that is, sizes and shapes of the first auxiliary sub-pixel Pag and the sub sub-pixel Ps, are defined by the auxiliary opening OPag and the sub opening OPs. A size of the sub sub-pixel Ps may be identical to the size of the main sub-pixel Pm shown in FIG. 15.

According to some embodiments, the auxiliary display element EDa may be connected to the auxiliary pixel circuit PCa, which is arranged apart from the auxiliary display element EDa, through the connection wiring CWL. For example, as described above, the auxiliary pixel circuit PCa may be apart from the auxiliary display element EDa and arranged in the pixel circuit part PCP. For example, the pixel circuit part PCP may be in the peripheral area DPA as shown in FIG. 3, or may be included in the second display area DA2 and located outside the component area CA (see FIG. 4), as shown in FIG. 4. In the connection wiring CWL located on the first planarization layer 117, an end may be electrically connected to the auxiliary thin-film transistor TFTa through an auxiliary connection electrode CM′, and another end may be electrically connected to the pixel electrode 210a of the auxiliary display element EDa. The connection wiring CWL may pass the transmission area TA of the second display area DA2.

The pixel electrode 210s of the sub display element EDs and the pixel electrode 210a of the auxiliary display element EDa may be connected to each other through the pixel connection wiring PCW. In the pixel connection wiring PCW located on the first planarization layer 117, an end may be electrically connected to the pixel electrode 210a of the auxiliary display element EDa, and another end may be electrically connected to the pixel electrode 210s of the sub display element EDs. The pixel connection wiring PWC may pass the transmission area TA of the second display area DA2. According to some embodiments, the pixel connection wiring PCW and the connection wiring CWL may be respectively located on different layers. For example, a third planarization layer may be between the first planarization layer 117 and the second planarization layer 118, and the pixel connection wiring PCW may be located on the third planarization layer.

The pixel connection wiring PCW may include conducting materials including Mo, Al, Cu, Ti, and the like, and may include a multi-layer or a single layer including the aforementioned materials. Alternatively, the pixel connection wiring PCW may include a transparent conducting material. For example, the pixel connection wiring PCW may include a transparent conducting oxide (TCO). The connection wiring CWL may include a conducting oxide such as indium tin oxide (ITO), indium zinc oxide (IZO), zinc oxide (ZnO), indium oxide (In₂O₃), indium gallium oxide (IGO), or aluminum zinc oxide (AZO).

The pixel electrode 210s of the sub display element EDs and a pixel electrode 210a of an auxiliary display element EDa adjacent to the sub display element EDs may be connected to each other and may be driven in response to a same signal. That is, the sub display element EDs and the auxiliary display element EDa may be driven by a same auxiliary pixel circuit PCa. Accordingly, the first auxiliary sub-pixel Pag and the sub sub-pixel Ps may emit light in response to a same signal.

Referring to FIG. 17, the auxiliary display element EDa and the auxiliary pixel circuit PCa may be connected to each other through the connection wiring CWL. In the connection wiring CWL located on the first planarization layer 117, an end may be connected to the auxiliary thin-film transistor TFTa through the auxiliary connection electrode CM′, and another end may be connected to the pixel electrode 210a of the auxiliary display element EDa.

The pixel electrode 210a of the auxiliary display element EDa and the pixel electrode 210s of the sub display element EDs may be electrically connected to each other through the pixel connection wiring PCW. In the pixel connection wiring PCW located on the second planarization layer 118, an end may be connected to the pixel electrode 210a of the auxiliary display element EDa, and another end may be connected to the pixel electrode 210s of the sub display element EDs. The pixel connection wiring PCW may be arranged in the transmission area TA of the second display area DA2.

The pixel connection wiring PCW may include a same material as the pixel electrode 210a of the auxiliary display element EDa and the pixel electrode 210s of the sub display element EDs. According to some embodiments, the pixel connection wiring PCW is an extend portion of each of the pixel electrode 210a of the auxiliary display element EDa and the pixel electrode 210s of the sub display element EDs, and the pixel electrode 210a of the auxiliary display element EDa and the pixel electrode 210s of the sub display element EDs may be integrally formed.

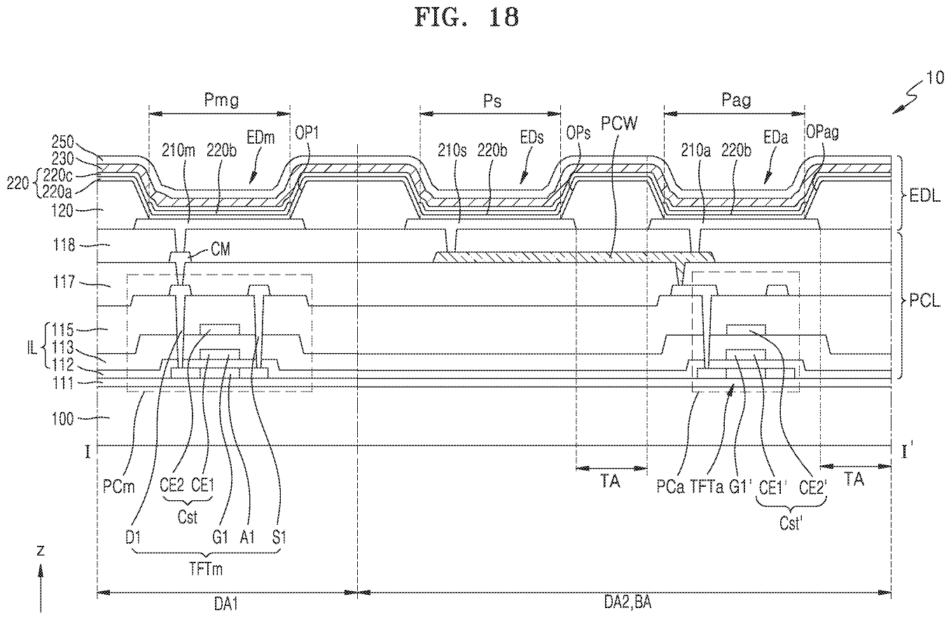

FIGS. 18 and 19 are cross-sectional views each schematically illustrating a portion of the display panel according to some embodiments. FIG. 18 is a cross-sectional view taken along the line I-I′ shown in FIG. 13A; and FIG. 19 is a cross-sectional view taken along the line II-II′ shown in FIG. 13B.

Referring to FIG. 1 auxiliary pixel circuit PCa8, the auxiliary display element EDa may overlap with the auxiliary pixel circuit PCa. That is, the auxiliary pixel circuit PCa may be in the second display area DA2. The pixel electrode 210a of the auxiliary display element EDa and the pixel electrode 210s of the sub display element EDs may be connected to each other through the pixel connection wiring PCW. In the pixel connection wiring PCW located on the first planarization layer 117, an end may be electrically connected to the pixel electrode 210a of the auxiliary display element EDa, and another end may be electrically connected to the pixel electrode 210s of the sub display element EDs. The pixel connection wiring PCW may pass the transmission area TA of the second display area DA2.

According to some embodiments, in the pixel connection wiring PCW located on the second planarization layer 118, an end may be connected to the pixel electrode 210a of the auxiliary display element EDa, and another end may be connected to the pixel electrode 210s of the sub display element EDs. The pixel connection wiring PCW is an extended portion of each of the pixel electrode 210a of the auxiliary display element EDa and the pixel electrode 210s of the sub display element EDs, and the pixel electrode 210a of the auxiliary display element EDa and the pixel electrode 210s of the sub display element EDs may be integrally formed.

As the pixel electrode 210a of the auxiliary display element EDa and the pixel electrode 210s of the sub display element EDs are connected through the pixel connection wiring PCW, the sub sub-pixel Ps and a first auxiliary sub-pixel Pag adjacent thereto may emit light in response to a same signal.

Referring to FIG. 19, the first main sub-pixel Pmg′ may be adjacent to a boundary between the first display area DA1 and the second display area DA2. The pixel electrode 210m of the main display element EDm, which is included in the first main sub-pixel Pmg′, and the pixel electrode 210s of the sub display element EDs may be connected to each other through the pixel connection wiring PCW. In the pixel connection wiring PCW located on the first planarization layer 117, an end may be electrically connected to the pixel electrode 210m of the main display element EDm, and another end may be electrically connected to the pixel electrode 210s of the sub display element EDs. According to some embodiments, at least a portion of the pixel connection wiring PCW may include a TOC. According to some embodiments, the pixel connection wiring PCW may include a same material as a material of the connection electrode CM (see FIG. 15).

As the pixel electrode 210m of the main display element EDm and the pixel electrode 210s of the sub display element EDs are connected with each other through the pixel connection wiring PCW, the sub sub-pixel Ps and the first main sub-pixel adjacent thereto may emit light in response to a same signal. Although the display device has been mainly described, the embodiments are not limited thereto. For example, a method of manufacturing a display device, which is used for manufacturing the display device, is also in the scope of the embodiments.

According to the embodiments, a display panel including an extended display area and a display device including the display panel may be implemented, by which images may be displayed an area in which components, which are electronic elements, are arranged. However, the scope of the embodiments are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a substrate comprising a first area and a second area;
a plurality of main sub-pixels in the first area;
a plurality of auxiliary sub-pixels in the second area; and
a plurality of sub sub-pixels adjacent to a first boundary of the second area in a first direction,
wherein the plurality of auxiliary sub-pixels comprise a plurality of first auxiliary sub-pixels in a first auxiliary line that is a virtual line extending in the first direction, and a plurality of second auxiliary sub-pixels and a plurality of third auxiliary sub-pixels alternately arranged in a second auxiliary line that is a virtual line parallel to the first auxiliary line, and
each of the plurality of sub sub-pixels is between a second auxiliary sub-pixel and a third auxiliary sub-pixel neighboring each other in the first direction.

2. The display panel of claim 1, wherein the first auxiliary sub-pixel, the second auxiliary sub-pixel, the first auxiliary sub-pixel, and the third auxiliary sub-pixel are repeatedly arranged in a third auxiliary line that is a virtual line extending in a second direction orthogonal to the first direction.

3. The display panel of claim 1, wherein centers of the plurality of sub sub-pixels overlap with the second auxiliary line.

4. The display panel of claim 1, wherein the plurality of sub sub-pixels and the first auxiliary sub-pixels are configured to emit light of a same color.

5. The display panel of claim 1, wherein a pixel electrode of any one sub sub-pixel of the plurality of sub sub-pixels is electrically connected to a pixel electrode of a first auxiliary sub-pixel adjacent to the any one sub sub-pixel.

6. The display panel of claim 5, further comprising a transparent wiring connecting the pixel electrode of the any one sub sub-pixel and the pixel electrode of the first auxiliary sub-pixel adjacent to the any one sub sub-pixel.

7. The display panel of claim 5, wherein the pixel electrode of the any one sub sub-pixel and the pixel electrode of the first auxiliary sub-pixel adjacent to the any one sub sub-pixel are integral with each other.

8. The display panel of claim 1, wherein the plurality of main sub-pixels comprise a plurality of first main sub-pixels in a first main line that is a virtual line extending in the first direction, and a plurality of second main sub-pixels and a plurality of third main sub-pixels alternately arranged in a second main line that is a virtual line parallel to the first main line, and
centers of the first main sub-pixels in the first main line and centers of the second main sub-pixels and the third main sub-pixels arranged in the second main line are arranged in a zig-zag manner.

9. The display panel of claim 8, wherein the second auxiliary line and a first main line neighbor each other with the first boundary therebetween.

10. The display panel of claim 8, wherein the plurality of sub sub-pixels and the first main sub-pixels are configured to emit light of a same color.

11. The display panel of claim 8, wherein an area of an emission area of each of the plurality of sub sub-pixels is identical to an area of an emission area of each of the first main sub-pixels.

12. The display panel of claim 8, wherein the pixel electrode of any one sub sub-pixel of the plurality of sub sub-pixels is electrically connected to a pixel electrode of the first main sub-pixel adjacent to the any one sub sub-pixel.

13. A display device comprising:
a display panel, comprising a first area having a plurality of main sub-pixels and a second area having a plurality of auxiliary sub-pixels; and
a component under the display panel to correspond to the second area,
wherein the display panel comprises:
a substrate comprising a first area and a second area;
a plurality of main sub-pixels in the first area;
a plurality of auxiliary sub-pixels in the second area; and
a plurality of sub sub-pixels adjacent to a first boundary of the second area in a first direction,
wherein the plurality of auxiliary sub-pixels comprises a plurality of first auxiliary sub-pixels in a first auxiliary line that is a virtual line extending in the first direction, and a plurality of second auxiliary sub-pixels and a plurality of third auxiliary sub-pixels alternately arranged in a second auxiliary line that is a virtual line parallel to the first auxiliary line, and
each of the plurality of sub sub-pixels is between the second auxiliary sub-pixel and the third auxiliary sub-pixel neighboring each other in the first direction.

14. The display device of claim 13, wherein the first auxiliary sub-pixel, the second auxiliary sub-pixel, the first auxiliary sub-pixel, and the third auxiliary sub-pixel are repeatedly arranged in a third auxiliary line that is a virtual line extending in a second direction orthogonal to the first direction.

15. The display device of claim 13, wherein centers of the plurality of sub sub-pixels are in the second auxiliary line.

16. The display device of claim 13, wherein the plurality of sub sub-pixels and the first auxiliary sub-pixels are configured to emit light of a same color.

17. The display device of claim 13, wherein a pixel electrode of the any one sub sub-pixel of the plurality of sub sub-pixels is electrically connected to a pixel electrode of the first auxiliary sub-pixel adjacent to the any one sub sub-pixel.

18. The display device of claim 13, wherein the plurality of main sub-pixels comprise a plurality of first main sub-pixels in a first main line that is a virtual line extending in the first direction, and a plurality of second main sub-pixels and a plurality of third main sub-pixels alternately arranged in a second main line that is a virtual line parallel to the first main line, and
centers of the first main sub-pixels in the first main line, and centers of the second main sub-pixels and the third main sub-pixels in the second main line, are arranged in a zig-zag configuration.

19. The display device of claim 18, wherein the second auxiliary line and a first main line neighbor each other with the first boundary therebetween.

20. The display device of claim 18, wherein the plurality of sub sub-pixels and the first main sub-pixels are configured to emit light of a same color.

21. The display device of claim 18, wherein an area of an emission area of each of the plurality of sub sub-pixels is identical to an area of an emission area of each of the first main sub-pixels.

22. The display device of claim 18, wherein a pixel electrode of any one sub sub-pixel of the plurality of sub sub-pixels is electrically connected to a pixel electrode of the first main sub-pixel adjacent to the any one sub sub-pixel.

23. A display device comprising:
a display panel, comprising a first area having a plurality of main sub-pixels and a second area having a plurality of auxiliary sub-pixels; and
a component under the display panel to correspond to the second area,
wherein the display panel comprises:
a substrate comprising a first area and a second area;
a plurality of main sub-pixels in the first area;
a plurality of auxiliary sub-pixels in the second area; and
a plurality of sub sub-pixels adjacent to a first boundary between the first area and the second area, and
the sub sub-pixel and some of the plurality of main sub-pixels are connected to a same pixel circuit, and a pixel electrode of the sub sub-pixel is connected to a pixel electrode of a main sub-pixel through a pixel connection wiring.

24. The display device of claim 13, wherein a pixel circuit of a main sub-pixel, which is in the first area and is not connected to the sub sub-pixel, is different from a pixel electrode of a main sub-pixel connected to the sub sub-pixel.
